(19) United States
(12) Patent Application Publication
(10) Pub. No.: US 2025/0357728 A1
(43) Pub. Date: Nov. 20, 2025

(54) SEMICONDUCTOR LASER PUMPED SOLID STATE LASER

(71) Applicant: KYOCERA SOC Corporation, Yokohama (JP)

(72) Inventors: Masami HATORI, Yokohama (JP); Masaki HARADA, Yokohama (JP)

(21) Appl. No.: 19/198,765

(22) Filed: May 5, 2025

(30) Foreign Application Priority Data
May 16, 2024 (JP) 2024-080465
Mar. 3, 2025 (JP) 2025-033024

(51) Int. Cl. H01S 5/20; H01S 5/125; H01S 5/323

(52) U.S. Cl. CPC H01S 5/2027; H01S 5/125; H01S 5/32341

(57) ABSTRACT

High output power and stable operation are achieved in a semiconductor laser pumped solid state laser. An LD pumped solid state laser 10 includes a solid state laser crystal 19 such as a Pr:YLF crystal, an LD 11 that emits a pumping light beam L to pump the laser crystal 19, a resonator that resonates the light emitted from the solid state laser crystal 19, and a wavelength control means such as a narrow bandpass filter 13 to cause an emission wavelength of the pumping light beam L by the LD 11 to match an absorption peak wavelength of the solid state laser crystal 19.

### CROSS REFERENCE TO RELATED APPLICATIONS

The present application claims priority under 35 U.S.C. § 119 to Japanese Patent Application No. 2024-080465, filed on May 16, 2024 and Japanese Patent Application No. 2025-033024, filed on Mar. 3, 2025. The above applications are hereby expressly incorporated by reference, in its entirety, into the present application.

### BACKGROUND

The present disclosure is related to a semiconductor laser pumped solid state laser. Particularly, the present disclosure is related to a solid state laser in which a solid state laser crystal is pumped as a laser medium by a pumping light beam which emitted by a semiconductor laser to generate laser oscillation.

As in the detailed example disclosed in Japanese Unexamined Patent Publication No. 2001-36176 (Patent Document 1), for example, a laser diode pumped solid state laser in which a solid state laser crystal, such as a YLF crystal doped with Pr³⁺ (hereinafter referred to as Pr:YLF crystal), is pumped by a pumping light beam emitted from a semiconductor laser (laser diode, hereinafter referred to as LD), and light emitted from the pumped solid state laser crystal is caused to resonate by a resonator is known. A YAG crystal doped with Nd³⁺ (hereinafter referred to as Nd:YAG crystal) or the like may also be applied as a solid state laser crystal, as disclosed in Japanese Unexamined Patent Publication No. 2001-36175 (Patent Document 2).

Pr:YLF crystals absorb light at wavelengths of 442 nm, 444 nm, 469 nm, and 479 nm, are capable of generating laser oscillation at wavelengths from 479 to 720 nm, and are extremely attractive as laser crystals. However, Pr:YLF crystals have a narrow absorption wavelength range. Therefore, when applied to semiconductor laser pumped solid state lasers, high power and stable laser oscillation are not possible unless the emission wavelength of the pumping LD matches the absorption wavelength and further the emission wavelength range is 0.5 to 1 nm or less. Note that if the above absorption wavelengths and emission wavelengths are explained in more detailed and realistic terms, they are not fixed as a pinpoint shape, but rather have a waveform that extends over certain ranges. In the case that a specific numerical value is given for a wavelength, the numerical value refers to a peak wavelength of the waveform (which may also be the center wavelength of the waveform).

However, commercially available pumping GaN based LDs that can oscillate light in the 400 nm band, which is the absorption wavelength band of Pr:YLF crystals, have a emission wavelength variation of 5 to 10 nm. Therefore, selecting an LD with an emission wavelength that matches the above absorption wavelength band will result in a yield of several percent. Taking the fact that that the unit price of LDs is approximately 100,000 yen into consideration, the cost of the LDs alone would exceed 1 million yen. For this reason, it is extremely difficult to achieve practical industrial mass production. The LDs also have an emission wavelength width of approximately 2 nm, which is wider than the absorption wavelength width of Pr:YLF crystals. Therefore, even if the wavelengths were matched, the absorption efficiency would be reduced. In addition, LDs have a characteristic that their emission wavelength fluctuates depending on light output and temperature. Therefore, it is extremely difficult to match the emission wavelength of LDs with the absorption wavelength of Pr:YLF crystals and to mass produce them.

Journal of Applied Physics, Vol. 85, pp. 857-858 (Non-Patent Document 1) discloses that LDs are selected for utilization such that their emission wavelength matches the absorption wavelength of Pr:YLF crystals. However, even when LDs are selected and utilized in such a manner, if the emission wavelength of the LD fluctuates depending on temperature, it will be impossible to achieve stable high power laser oscillation.

In order to match the emission wavelength of a pumping LD with the absorption wavelength of a Pr:YLF crystal, a broad area LD with a relatively wide emission wavelength range may be employed as an LD. However, although broad area LDs have high output, they have the disadvantage of poor spatial coherence due to their transverse mode being a multimode. Therefore, even if an external resonator is formed to control the emission wavelength and provide feedback to the LD, optical loss increases, and eventually it becomes difficult to control the emission wavelength of the pumping LD to a desired value.

### SUMMARY

The present disclosure has been developed in view of the foregoing circumstances. The present disclosure achieves high output power and stable operation in a LD pumped solid state laser in which a solid state laser crystal such as a Pr:YLF crystal is pumped by an LD.

An LD pumped solid state laser according to the present disclosure includes:
a solid state laser crystal such as a Pr:YLF crystal,
an LD that emits a pumping light beam to pump the solid state laser crystal,
a resonator that resonates the light emitted from the solid state laser crystal when the solid state laser crystal is pumped, and
a wavelength control means for causing the emission wavelength of the pumping light beam emitted by the semiconductor laser to match an absorption peak wavelength of the solid state laser crystal.

Specifically, it is preferable for a bandpass filter that narrows the wavelength of the light to be resonated and is placed in the above resonator to be employed as the wavelength control means.

In addition, in the LD pumped solid state laser according to the present disclosure, it is preferable for:
an external resonator to be provided to constitute the wavelength control means,
the external resonator having a transmissive reflective mirror that transmits the pumping light beam emitted from the semiconductor laser toward the solid state laser crystal and reflects it back toward the semiconductor laser, and
the transmissive reflective mirror being formed from two glass plates coupled to each other.

In this case, the two glass plates are coupled to each other by optical contact, or coupled to each other by forming metal in the vicinity of the edge of each glass plate and heating and welding the metal plating, or coupled to each other by forming metal plating near the edge of each glass plate and a metal plate overlapping that metal plating and heating and welding those metal plates through the metal plating, or coupled to each other by melting low melting point glass placed near the edge of each glass plate. The metal plating and the metal plate overlapping the metal plating are formed near the edge of each glass plate, and the metal plates are coupled by heating and welding each other through the metal plating, or by melting low melting point glass placed near the edge of each glass plate.

Alternatively, it is preferable for the resonator to include a diffraction grating that selects the wavelength of light to be resonated. It is also preferable for the resonator to further include a VBG (Volume Bragg Grating) that selects the wavelength of the light to be resonated. It is also preferable for the resonator to further include a confocal optical system.

It is preferable for a GaN based LD to be employed as the pumping LD. It is also preferable for this pumping LD to be a multi transverse mode LD.

In addition, the LD pumped solid state laser according to the present disclosure may be further provided with an optical wavelength conversion element that shortens the wavelength of a laser beam.

According to the LD pumped solid state laser of the present disclosure, the wavelength of the pumping light beam emitted by the LD can be roughly matched to the absorption peak wavelength of the solid state laser crystal by using the wavelength control means as described above. Therefore, the yield of applicable LDs can be dramatically improved. because the emission wavelength of the pumping LD is stabilized with respect to the absorption wavelength of the solid state laser crystal, the light output of the solid state laser is also stabilized. In addition, even if the drive current value of the pumping LD or the ambient temperature changes and its emission wavelength fluctuates, the light output and related performance of the LD pumped solid state laser remain stable because the emission wavelength is maintained in a stable state with respect to the absorption wavelength of the solid state laser crystal.

Note that although not limited to such a configuration, an Nd:YAG laser is often employed as a pumping LD. In an Nd:YAG laser, the emission wavelength may deviate from the absorption wavelength of a solid state laser crystal depending on ambient temperature and other factors. To prevent such deviations, it is possible to fix the emission wavelength by adjusting the temperature of the pumping LD. Meanwhile, the temperature of the resonator of the solid state laser is also often adjusted to stabilize light output and emission mode. The temperature adjustment of the resonator is generally different from that of the pumping LD. Therefore, in such a case, separate temperature adjustment functions will be required, resulting in the size and cost of the LD pumped solid state laser becoming increasing. The LD pumped solid state laser of the present disclosure does not require separate temperature control functions. Therefore, increased size and cost can be avoided from this point as well.

### BRIEF DESCRIPTION OF THE DRAWINGS

FIG. 1 is a schematic side view of an LD pumped solid state laser according to a first embodiment of the present disclosure.

FIG. 2 is a collection of diagrams that illustrate light spectra of a pumping LD in the configuration illustrated in FIG. 1 for each of a plurality of drive current values.

FIG. 3 is a collection of diagrams that illustrate light spectra of a pumping LD in the configuration illustrated in FIG. 1, for each of a plurality of drive current values.

FIG. 4 is a graph that shows emission wavelengths with and without wavelength control in the configuration illustrated in FIG. 1.

FIG. 5 is a graph that shows emission wavelength ranges with and without wavelength control in the configuration illustrated in FIG. 1.

FIG. 6 is a schematic diagram of an LD in the solid state laser of FIG. 1.

FIG. 7 is a graph that shows a light intensity distribution of a pumping light beam in a fast axis direction in the solid state laser of FIG. 1.

FIG. 8 is a graph that shows the light intensity distribution of the pumping light beam in the direction of the slow axis in the solid state laser of FIG. 1.

FIG. 9 is a collection of diagrams that illustrate light spectra of the pumping light beam in the solid state laser of FIG. 1 for each of a plurality of drive current values.

FIG. 10 is a graph that shows transmission characteristics of solid state laser crystals.

FIG. 11 is a graph that shows lasing characteristics of the solid state laser according to the present disclosure.

FIG. 12 is a schematic side view of, an LD pumped solid state laser according to a second embodiment of the present disclosure.

FIG. 13 is a side view of a portion of the LD pumped solid state laser of FIG. 12.

FIG. 14 is a diagram that illustrates the spectrum of a pumping light beam with wavelength control in the device illustrated in FIG. 12.

FIG. 15 is a schematic side view of an LD pumped solid state laser according to a third embodiment of the present disclosure.

FIG. 16 is a diagram that illustrates the spectrum of a pumping light beam in the case that wavelength control is exerted by an apparatus of the present disclosure.

FIG. 17 is a diagram that illustrates the spectrum of a pumping light beam in the case that wavelength control is not exerted by the apparatus of the present disclosure.

FIG. 18 is a diagram that illustrates absorption and emission properties of a Pr:YLF crystal.

FIG. 19 is a graph that shows the relationship between drive current values and emission wavelengths with and without wavelength control.

FIG. 20 is a graph that shows the relationship between drive current values and emission wavelength widths with and without wavelength control.

FIG. 21 is a schematic side view of an LD pumped solid state laser according to a fourth embodiment of the present disclosure.

FIG. 22 is a schematic side view of an LD pumped solid state laser according to a fifth embodiment of the present disclosure.

FIG. 23 is a schematic side view of an LD pumped solid state laser according to a sixth embodiment of the present disclosure.

FIG. 24 is a schematic side view of an LD pumped solid state laser according to a seventh embodiment of the present disclosure.

FIG. 25 is a schematic side view of an LD pumped solid state laser according to an eighth embodiment of the present disclosure.

FIG. 26 is a schematic side view of an LD pumped solid state laser according to a ninth embodiment of the present disclosure.

FIG. 27 is a schematic side view of an LD pumped solid state laser according to a tenth embodiment of the present disclosure.

FIG. 28 is a graph that shows examples of light outputs and wavelengths of wavelength converted waves obtained by the present disclosure.

FIG. 29 is a schematic side view of an LD pumped solid state laser according to an eleventh embodiment of the present disclosure.

FIG. 30 is a schematic side view of an LD pumped solid state laser according to a twelfth embodiment of the present disclosure.

FIG. 31 is a schematic side view of the main components of the apparatus illustrated in FIG. 30 prior to being coupled.

FIG. 32 is a schematic side view of the main components illustrated in FIG. 31 after being coupled.

FIG. 33 is a schematic side view of a LD pumped solid state laser showing deposited matter that forms on a transmissive planar mirror.

FIG. 34 is a schematic plan view of an example of a beam spot of a pumping light beam influenced by deposited matter.

FIG. 35 is a schematic diagram that illustrates an example of a normal beam profile of a pumping light beam.

FIG. 36 is a schematic diagram that illustrates an example of an abnormal beam profile of a pumping light beam.

FIG. 37 is a schematic side view of the main components of an apparatus according to a thirteenth embodiment of the present disclosure prior to being coupled.

FIG. 38 is a schematic side view of the main components illustrated in FIG. 37 after being coupled.

FIG. 39 is a schematic side view of the main components of an apparatus according to a fourteenth embodiment of the present disclosure prior to being coupled.

FIG. 40 is a schematic side view of the main components illustrated in FIG. 39 after being coupled.

FIG. 41 is a schematic side view of the main components of an apparatus according to a fifteenth embodiment of the present disclosure prior to being coupled.

FIG. 42 is a schematic side view of the main components illustrated in FIG. 41 after being coupled.

### DETAILED DESCRIPTION OF THE PREFERRED EMBODIMENTS

Embodiments of the present disclosure will be described below with reference to the drawings.

### First Embodiment

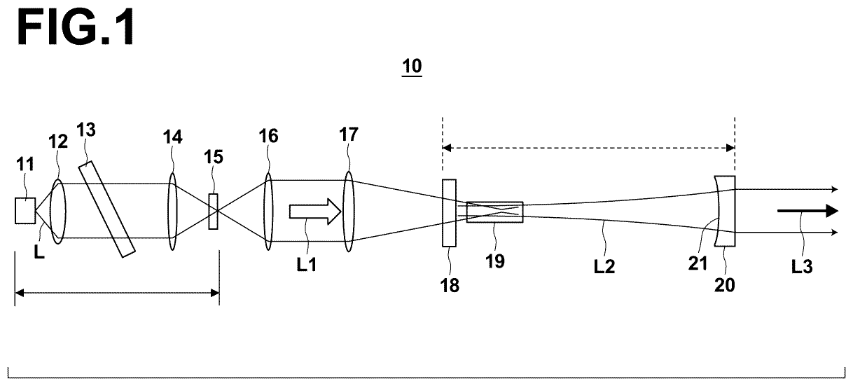

FIG. 1 illustrates the schematic configuration of an LD pumped solid state laser 10 according to a first embodiment of the present disclosure. The LD pumped solid state laser 10 is constituted by elements which are disposed from a pumping LD 11 to a concave mirror 20 for a resonator positioned forward (toward the right in the figure) along the optical axis of the pumping LD 11. These elements will be described in order below. The pumping LD 11 emits a laser by itself and emits a pumping light beam L as a spreading light beam. The pumping light beam L is collimated by a collimating lens 12, and the collimated light beam passes through a narrow band BPF (band pass filter) 13 as a wavelength control means and enters a focusing lens 14. The incident collimated light beam is focused by the focusing lens 14 to be focused onto a front facet of a transmissive planar mirror 15, and then passes through the mirror 15.

The pumping light beam L transmitted through the transmissive planar mirror 15 is collimated by a collimating lens 16, and the collimated light beam is focused by a focusing lens 17. The focused pumping light beam L passes through a planar mirror 18, enters a rod-shaped Pr:YLF crystal 19, and is focused within the crystal 19. The direction of travel of the pumping light beam incident on the Pr:YLF crystal 19 is denoted as L1 in the figure when the light is in the collimated state described above. The wavelength of the pumping light beam L1 is controlled to be in a narrow wavelength band mainly centered at 444 nm by passing through the narrow band BPF 13.

The Pr:YLF crystal 19 that the pumping light beam L1, the wavelength of which is controlled to be mainly centered at 444 nm, emits a light beam L2 with an output peak at a wavelength of 640 nm or the like by induced emission. The light beam L2 resonates in a resonator of the solid state laser, which is constituted by the transmissive planar mirror 18 and the concave mirror 20 described above, and is output from the concave mirror 20 as a high intensity solid state laser beam L3. Note that the concave surface of the concave mirror 20, that is, the surface that faces the planar mirror 18, is coated with a coating 21 that allows the light of 640 nm wavelength to partially pass therethrough and reflects the remainder. As described above, the high intensity laser beam L3 is stably output from the LD pumped solid state laser 10. Note that in FIG. 1, a resonating range of the solid state laser is indicated by a dashed arrow having two ends and a resonating range for wavelength control is indicated by a solid arrow having two ends (the same applies hereinafter).

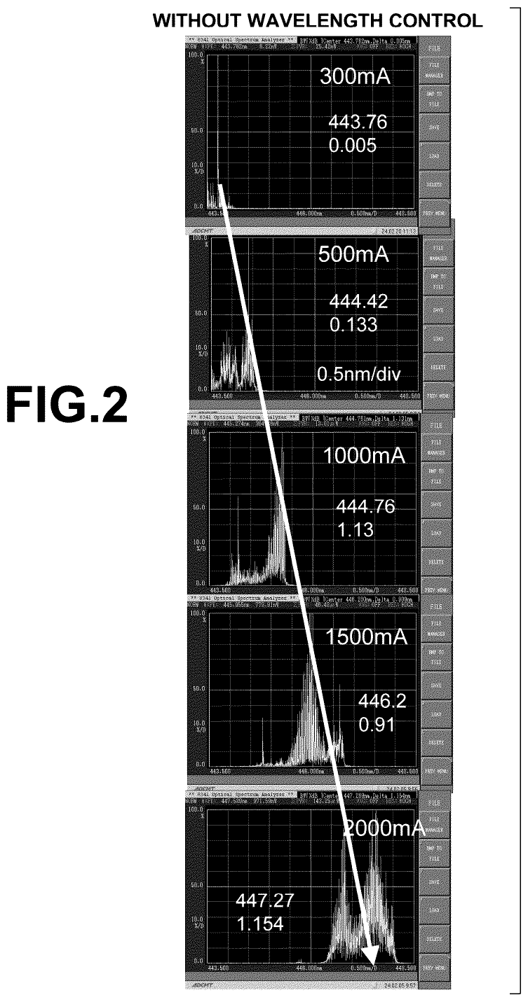

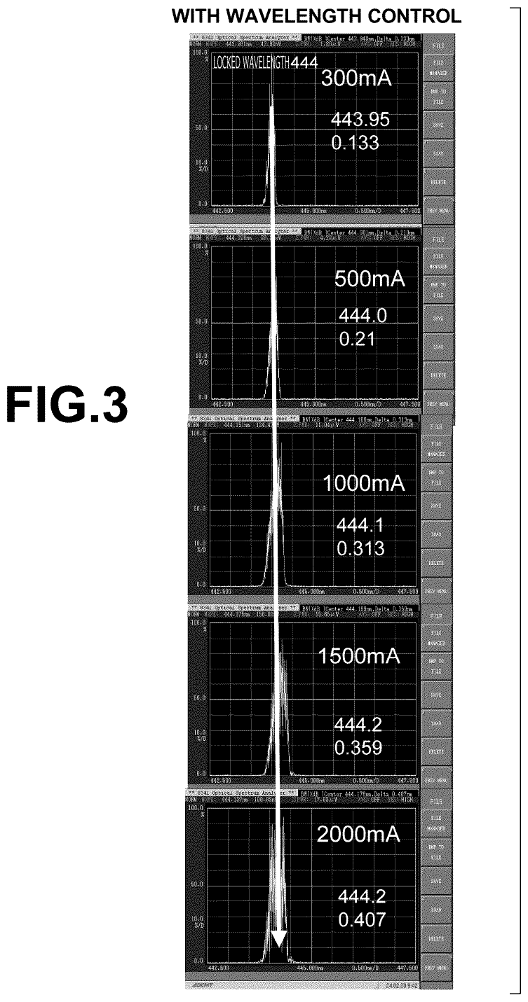

FIG. 2 illustrates light spectra of a GaN-based broad area LD with an emission wavelength in the vicinity of 444 nm, as actually measured by instruments. From top to bottom, the light spectra were obtained at drive current values of 300 mA, 500 mA, 1000 mA, 1500 mA, and 2000 mA. The emission wavelength shifted from 443.76 nm to 447.27 nm as the current value was increased. The amount of wavelength shift was 3.51 nm. In contrast, wavelength control employing the BPF 13 of FIG. 1 resulted in the light spectra illustrated in FIG. 3. These are also light spectra at current values of 300 mA, 500 mA, 1000 mA, 1500 mA, and 2000 mA, from top to bottom. The emission wavelength shifted only slightly from 443.95 nm to 444.19 nm. The wavelength shift was 0.24 nm. That is, the amount of wavelength shift for accompanying changes in current values was about 1/15 of that without wavelength control. In this manner, it was found that wavelength control can stably excite the Pr:YLF crystal 19 without significant wavelength shift even if the drive current value is increased or decreased.

In addition, if the cases in which the drive current value is 2000 mA is focused on, the emission wavelength is 444.19 nm with wavelength control compared to 447.27 nm without wavelength control, resulting in a difference of about 3 nm. Generally, it can be said that wavelength control is facilitated the greater this difference is. The fact that wavelength control is possible even when the wavelengths are separated by about 3 nm means that, for example, it is possible to utilize LDs with wavelengths that differ by up to ±3 nm from the center wavelength of 444 nm. This means that almost 100% of commercially available LDs can be utilized, and the yield of LDs can be increased.

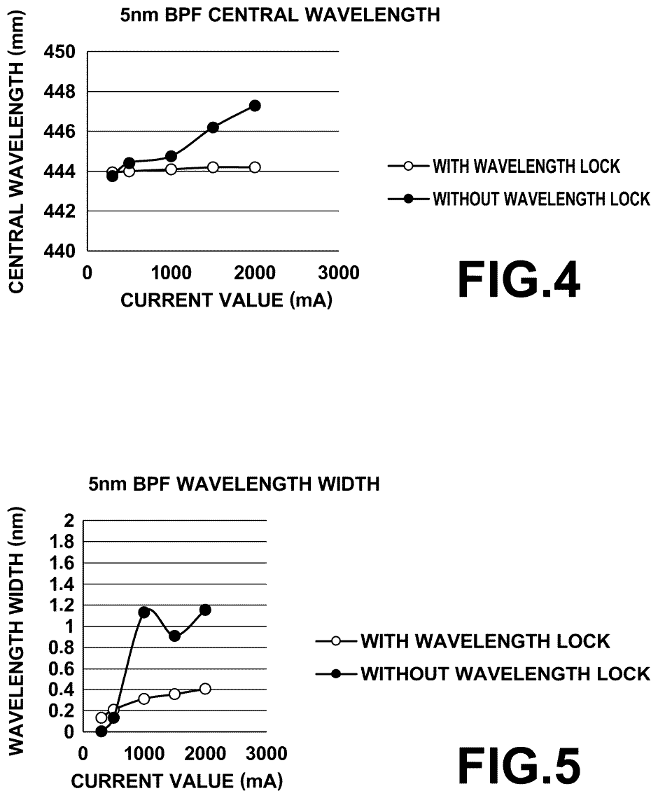

Meanwhile, FIG. 4 illustrates a comparison of emission wavelengths for a case in which wavelength control is exerted and a case in which wavelength control is not exerted. Wavelength fluctuations are smaller in the case in which wavelength control is exerted than those in the case in which wavelength control is not exerted. In addition, FIG. 5 illustrates a comparison of emission wavelength widths a case in which wavelength control is exerted and a case in which wavelength control is not exerted. The spread of the emission wavelength width is smaller in the case in which wavelength control is exerted than that in the case in which wavelength control is not exerted, and is 0.4 nm or less. At this value, there is practically no decrease in absorption efficiency in the Pr:YLF crystal 19, and therefore various LDs may be employed to pump the Pr:YLF crystal 19.

The LD pumped solid state laser 10 illustrated in FIG. 1 has an optical system in which the resonator is a so-called a confocal optical system. That is, in the LD pumped solid state laser 10, a resonator is formed between the pumping LD 11 and the front end facet of the transmissive planar mirror 15. The pumping light beam L emitted from the pumping LD 11 is collimated by the collimating lens 12, and the collimated light beam is focused by the focusing lens 14 to be focused at the front end facet of the transmissive planar mirror 15, where the reflectance is 35%. Such a resonator with a confocal optical system is characterized by its resistance to mechanical system fluctuations due to environmental temperature and other factors, and its ability to maintain stable light output. For example, even if the position or angle of the mirror 15 deviates slightly from a designed value, the reflected light from the mirror 15 returns almost entirely to the pumping LD 11, realizing a stable resonator.

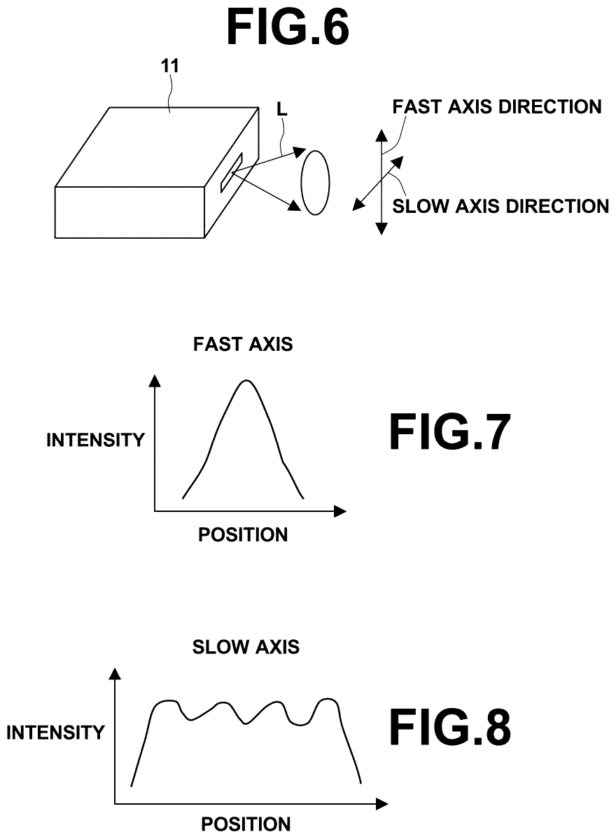

FIG. 6 illustrates the schematic configuration of the pumping LD 11. The pumping light beam L emitted from the LD 11 has spatial coherence in the direction of a vertical fast axis direction (the vertical direction in FIG. 1). Therefore, the pumping light beam L is emitted as a Gaussian beam. Meanwhile, in the direction of a slow axis, which is perpendicular to the fast axis, there are multiple transverse modes. Therefore, the pumping light beam L has poor spatial coherence and is not a Gaussian beam, but has a diffuse intensity. The above is schematically illustrated in FIGS. 7 and 8. FIG. 7 illustrates an intensity distribution of the Gaussian beam in the direction of the fast axis. FIG. 8 illustrates an intensity distribution in the direction of the slow axis, in which the beam intensity fluctuates and the spatial coherence is poor. Therefore, wavelength control is considered difficult even if a resonator is formed to perform wavelength control for the pumping light beam L of a multi transverse mode having poor spatial coherence, because the beam from the resonator will not return efficiently to the pumping LD 11. In actuality, wavelength control was attempted by applying an LD with an emission wavelength of 808 nm and is of a multi transverse mode in the slow axis to the same optical system as that illustrated in FIG. 1. However, wavelength control was not possible. Considering that it is possible to conduct wavelength control for LDs with a single mode in the slow axis, it is presumed that the reason for the difficulty in wavelength control described above is because the transverse mode is multimode. Meanwhile, it was confirmed for the first time that it is possible to conduct wavelength control for GaN based LDs with an emission wavelength of 444 nm even if they have multiple transverse modes. The detailed reason for this is unknown, but it may be due to the configuration of GaN based LDs.

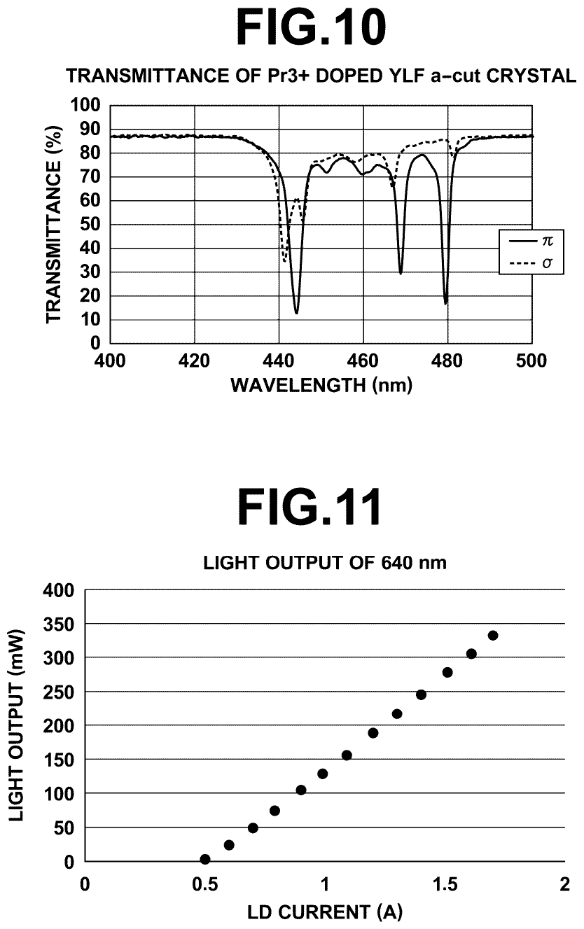

The configuration illustrated in FIG. 1 will be described in greater detail. The Pr:YLF crystal 19 employed here is doped with Pr³⁺ at 0.5% and has a crystal length of 6 mm. The Pr:YLF crystal 19 has the spectral characteristics illustrated in FIG. 10. In FIG. 10, the vertical axis represents transmittance and the horizontal axis represents wavelength. π represents these properties when the polarization direction of the Pr:YLF crystal 19 is parallel to the crystal c-axis, and σ represents these properties when the polarization direction of the Pr:YLF crystal 19 is perpendicular to the crystal c-axis. As illustrated in FIG. 10, the absorption line widths of the Pr:YLF crystal 19 are narrow and the tips thereof are not flat but sharp. Therefore, it can be understood that the absorption efficiency of the Pr:YLF crystal 19 is higher for a narrower emission wavelength width.

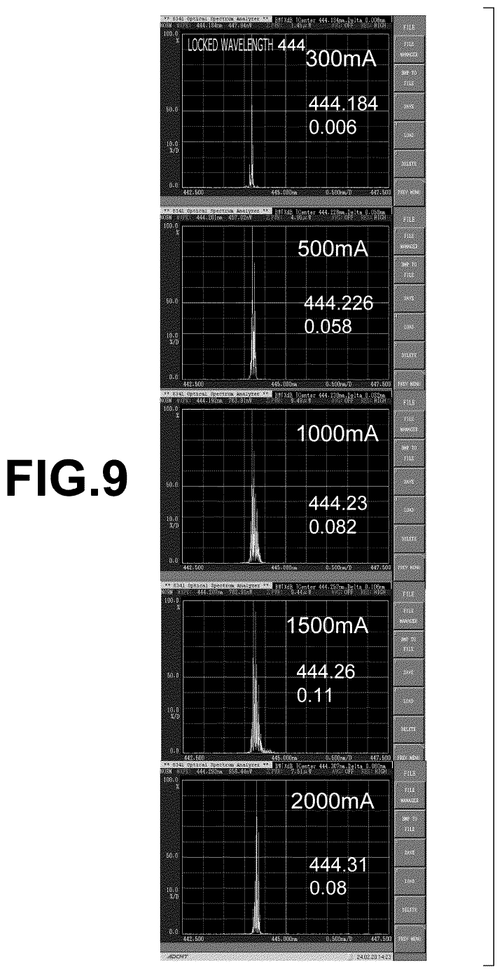

FIG. 9 illustrates light spectra of the pumping light beam for each of a plurality of drive current values when the Full Width at Half Maximum (FWHM) of the BPF 13 of FIG. 1 is 1 nm, in the case that wavelength control is exerted while changing a drive current value to 300 mA, 500 mA, 1000 mA, 1500 mA, and 2000 mA. In the diagrams for each drive current value, the value in the upper row below the drive current value is the emission wavelength, and the value in the lower row is the emission wavelength width. It can be understood that the emission wavelength widths are narrower than those of a BPF with a FWHM of 5 nm. When the drive current value is 2000 mA, the emission wavelength width is 0.08 nm, for example. On the other hand, when the BPF13 has a FWHM of 5 nm, the value is 0.407 nm (refer to FIG. 3). Therefore, the BPF13 with a FWHM of 1 nm has a narrower emission wavelength width. In addition, the absorption efficiency in the Pr:YLF crystal 19 is greater for a BPF13 with a FWHM of 1 nm than for a BPF13 with a FWHM of 5 nm. Note that it was confirmed that wavelength control is possible for a BPF13 with an FWHM of 1 nm or 2 nm in addition to an FWHM of 5 nm.

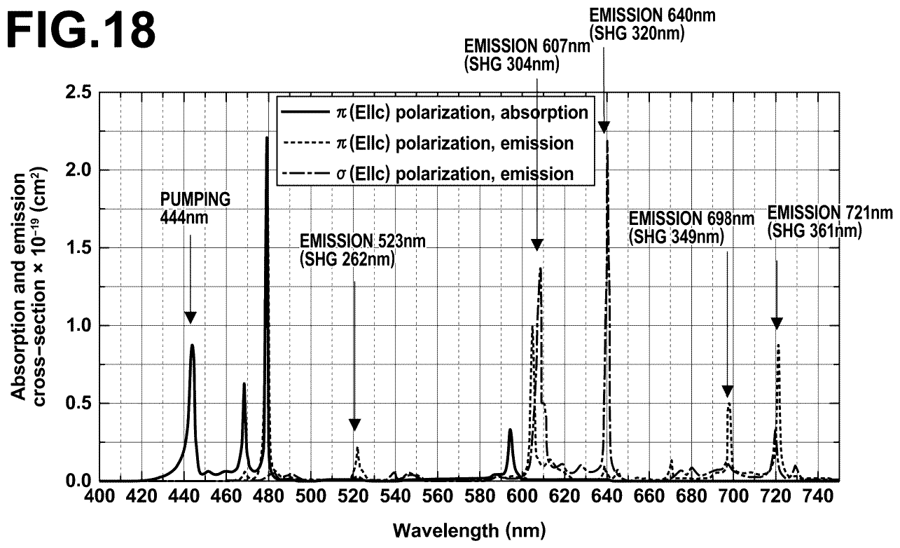

As described above, Pr:YLF crystal 19 has the spectral characteristics illustrated in FIG. 10, and the transmittance represented by the vertical axis of the graph indicates the absorption characteristics of the crystal 19. Considering these absorption properties, there is a peak absorption at a wavelength of 444 nm, and about 90% of the pumping light beam L at this wavelength of 444 nm is absorbed by the Pr:YLF crystal 19. Because the solid state laser is designed to lase at a wavelength of 640 nm in the lasing line of the Pr:YLF crystal 19 illustrated in FIG. 18, the absorbed energy causes the solid state laser to lase at a wavelength of 640 nm. FIG. 11 illustrates the lasing characteristics of the solid state laser. The horizontal axis represents the drive current value (A) of the pumping LD 11, and the vertical axis represents the light output (mW) of a solid state laser beam L3, which has a wavelength of 640 nm. When the drive current value of the pumping LD 11 is 1.7 A, the light output of the solid state laser beam L3 is 332 mW. Due to wavelength control, the wavelength of the pumping LD 11 does not change with the drive current value and remains within the absorption line width of the Pr:YLF crystal 19, confirming that the light output of the solid state laser beam L3 increases linearly with increasing drive current values. When the wavelength is not controlled, the above light output saturates or decreases because the emission wavelength shifts as the drive current value increases, but this did not occur in the LD pumped solid state laser 10 of the present embodiment.

Here, FIG. 18 illustrates the absorption and emission characteristics of the Pr:YLF crystal 19. The typical absorption line is 444 nm. On the other hand, the typical emission lines are 523 nm, 607 nm, 640 nm, 698 nm, and 721 nm. In the embodiment described above, the design is for solid state laser emission at a wavelength of 640 nm. However, it is also possible to achieve solid state laser emission at wavelengths other than 640 nm. In the case that an SHG (second harmonic) is to be generated, second harmonics having wavelengths of 262 nm, 304 nm, 320 nm, 349 nm, and 361 nm are respectively obtained when the solid state laser emission lines are 523 nm, 607 nm, 640 nm, 698 nm, and 721 nm.

### Second Embodiment

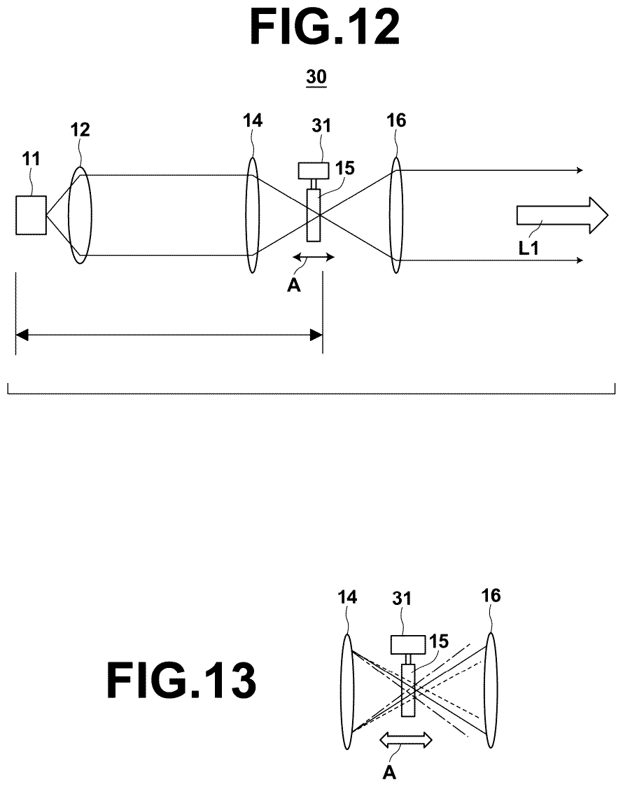

Next, an LD pumped solid state laser 30 according to a second embodiment of the present disclosure will be described with reference to FIGS. 12 and 13. FIG. 12 illustrates the schematic configuration of the LD pumped solid state laser 30. In the following figures, elements which are equivalent to those described thus far are denoted by the same reference numbers as those which were previously employed, and descriptions thereof will be omitted unless particularly necessary. In the LD pumped solid state laser 30, elements which are equivalent to those of the LD pumped solid state laser 10 illustrated in FIG. 1 are located in front of the collimating lens 16 (toward the right in the figure).

A mirror moving means 31 is connected to the transmissive planar mirror 15 located between the focusing lens 14 and the collimating lens 16 as a wavelength control means. The mirror moving means 31 is constituted by a drive source, such as a motor, and a drive force transmission mechanism, such as a rack and pinion, interposed between the drive source and the mirror 15. The mirror moving means moves the transmissive planar mirror 15 between the lenses 14 and 16 in the direction of arrow A, which is a direction parallel to the optical axes of the lenses 14 and 16, by the drive source being operated.

FIG. 13 illustrates the focusing lens 14, the transmissive planar mirror 15, the collimating lens 16, and the mirror moving means 31 as an extracted view. Here, the operation of movement of the transmissive planar mirror 15 described above is also illustrated. That is, when the moving position of the mirror 15 is set such that the pumping light beam L focused by the focusing lens 14 is focused at the output facet of the transmissive planar mirror 15, the longer wavelength pumping light beam L is focused farther away (toward the right in FIG. 9) and the shorter wavelength pumping light beam L is focused closer (toward the left in FIG. 13) due to wavelength dispersion by the focusing lens 14. The shorter wavelength pumping light beam Lis focused in the front (toward the left in FIG. 13). Thus, by adjusting the movement position of the transmissive planar mirror 15, the wavelength of the pumping light beam L incident on the Pr:YLF crystal 19 (refer to FIG. 1) can be adjusted to a narrow band of 444 nm even without the narrow band BPF 13 illustrated in FIG. 1. After the adjustment, the mirror 15 is fixed in the position that emits light having a wavelength of 444 nm. If the mirror moving means 31 is further disconnected from the mirror 15, a laser module suitable for actual use can be obtained.

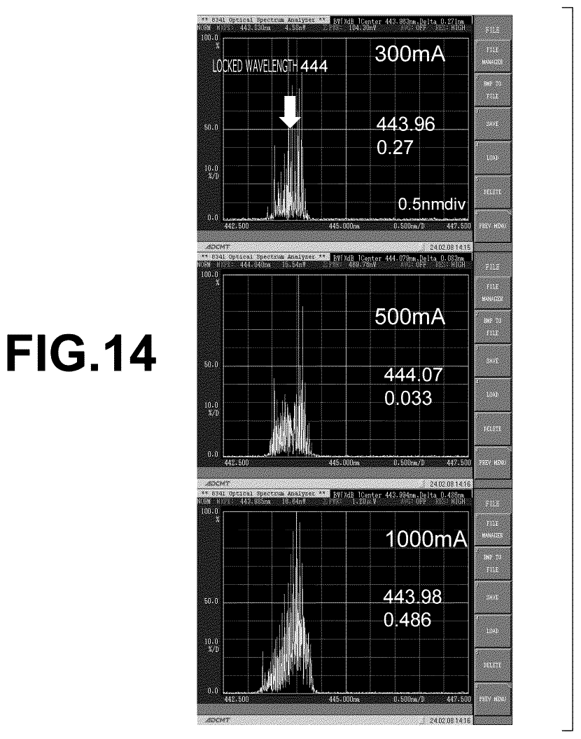

FIG. 14 illustrates the spectrum of the pumping LD 11 when the emission wavelength is controlled to be 444 nm by the mirror moving means 31 as the wavelength control means, for example. This illustration is similar to that of FIG. 3, with the light spectra at drive current values of 300 mA, 500 mA, and 1000 mA, in order from top to bottom. In each case, the emission wavelengths are controlled to be 443.96 nm, 444.07 nm, and 443.98 nm, respectively. The emission wavelength widths (FWHM) are 0.27 nm, 0.033 nm, and 0.486 nm, respectively, which are narrower than that of the case without wavelength control (0.5 nm or less). Therefore, absorption of the pumping light beam L by the Pr:YLF crystal 19 is favorable.

### Third Embodiment

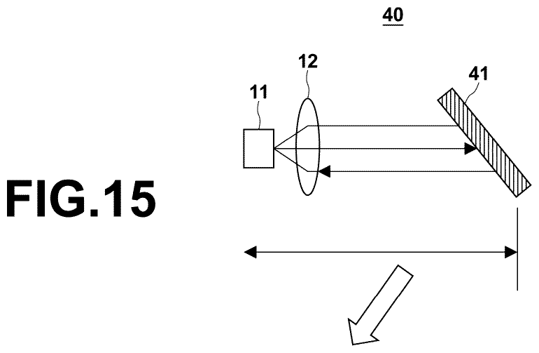

Referring next to FIG. 15, an LD pumped solid state laser 40 according to a third embodiment of the present disclosure will be described. FIG. 15 illustrates the configuration of a wavelength control means that the LD pumped solid state laser 40 is equipped with. In the present embodiment, a diffraction grating 41 is employed as the wavelength control means. That is, the LD pumped solid state laser 40 of the present embodiment employs a diffraction grating 41 instead of a narrow band BPF 13, in contrast to the configuration illustrated in FIG. 1. Note that the diffraction grating 41 has grooves at a pitch of 600 lines/mm. In the configuration illustrated in FIG. 15, the pumping light beam L emitted from the pumping LD 11 is collimated by the collimating lens 12, and the collimated pumping light beam L enters the diffraction grating 41. The pumping light beam L is diffracted by the diffraction grating 41, and the diffracted light (−1st order diffracted light) returns to the pumping LD 11. At this time, an external resonator is formed between the pumping LD 11 and the diffraction grating 41, and the wavelength of the pumping light beam L is controlled. In this case, the control wavelength can be selected by rotating the diffraction grating (rotation around an axis perpendicular to the display plane in FIG. 14).

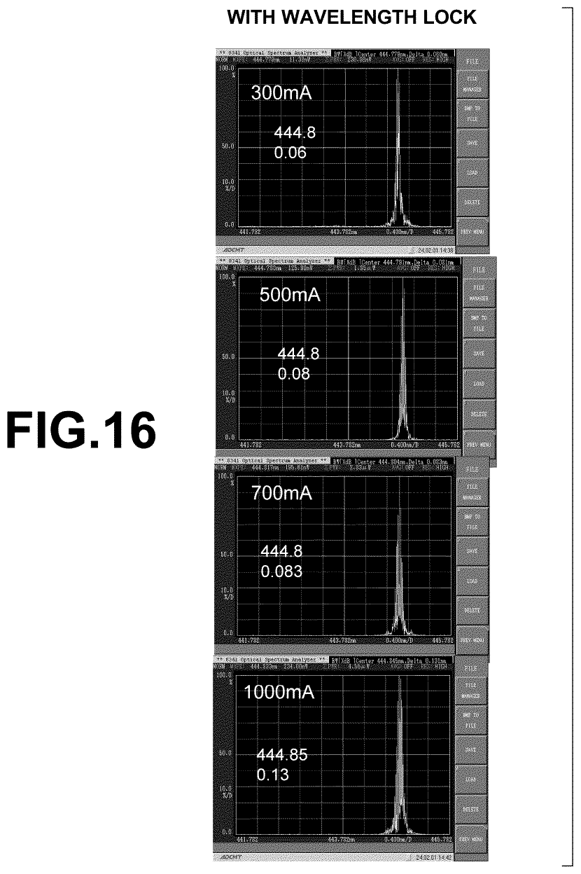

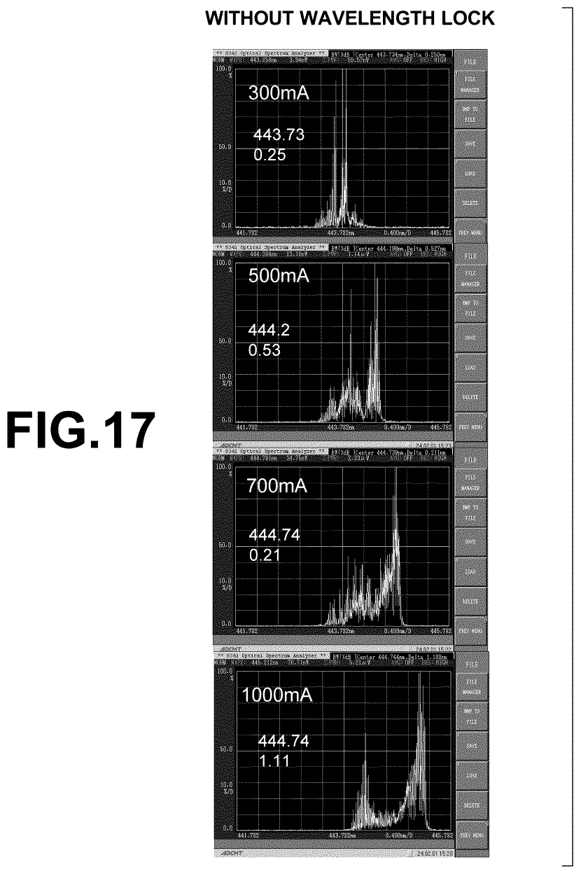

FIGS. 16 and 17 illustrate the light spectra of the pumping light beam L when the above wavelength control is applied (indicated as “with wavelength lock” in FIG. 16) and when it is not applied (indicated as “without wavelength lock” in FIG. 17), respectively. In the light spectra in the case that wavelength control is applied illustrated in FIG. 16, when the drive current of the pumping LD 11 is 300 mA, 500 mA, 700 mA, and 1000 mA, the emission wavelengths are 444.8 nm, 444.8 nm, 444.8 nm, and 444.85 nm, respectively, and the emission wavelength widths (FWHM) are 0.06 nm, 0.08 nm, 0.083 nm, and 0.13 nm, respectively. In this manner, it was found that the emission wavelength did not shift significantly even when the drive current value was increased.

On the other hand, in the light spectrum without wavelength control illustrated in FIG. 17, when the drive current of the pumping LD 11 was 300 mA, 500 mA, 700 mA, and 1000 mA, the emission wavelengths were 444.73 nm, 444.2 nm, 444.74 nm, and 444.74 nm, respectively, and the emission wavelength widths (FWHM) were 0.25 nm, 0.53 nm, 0.21 nm, and 1.11 nm, respectively. In this manner, the emission wavelength changed with the drive current values, and the emission wavelength width (FWHM) also changed with increases in the drive current value.

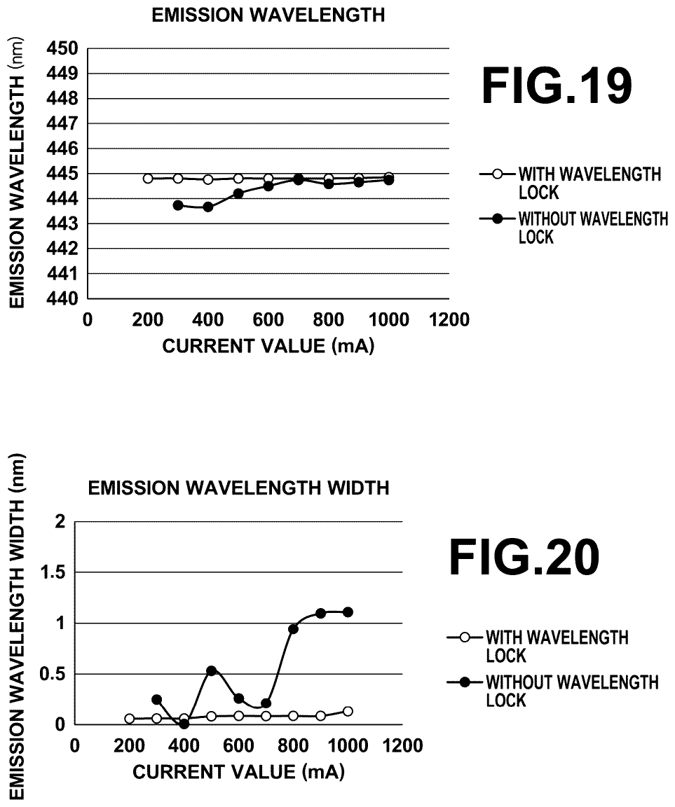

FIG. 19 is a graph having a greater number of measurement points than those in FIGS. 16 and 17 above. Here, the horizontal axis represents the drive current value (mA) of the pumping LD 11, and the vertical axis represents the emission wavelength (nm) of the pumping LD 11. As illustrated in the drawing, in this case, the emission wavelength fluctuates more significantly in response to changes in drive current values when wavelength control is not applied than when wavelength control is applied. FIG. 20 also illustrates the change in the emission wavelength width of the pumping LD 11 when the drive current value of the pumping LD 11 is changed. In this drawing, the horizontal axis represents the drive current value of the pumping LD 11 (mA), and the vertical axis represents the emission wavelength width of the pumping LD 11 (nm). In this case too, it can be seen that the emission wavelength width (FWHM) changes markedly with respect to the change in the above drive current value. As described above, if the emission wavelength of the LD is controlled, the emission wavelength of the LD can be caused to match the absorption wavelength of the Pr:YLF crystal 19 even when the drive current value of the LD is changed.

### Fourth Embodiment

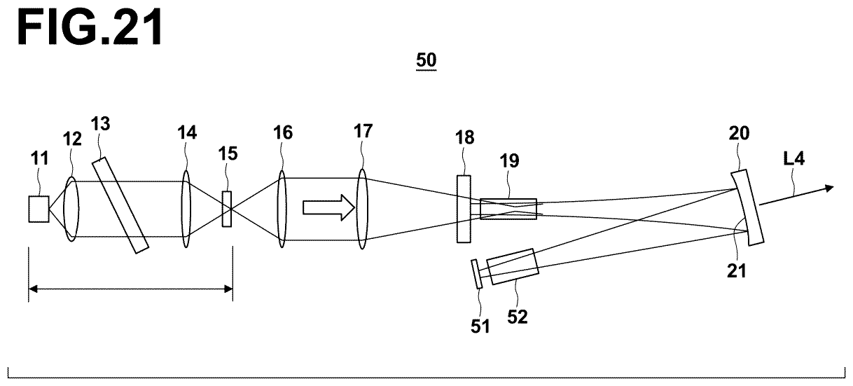

Referring next to FIG. 21, an LD pumped solid state laser 50 according to a fourth embodiment of the present disclosure will be described. FIG. 21 illustrates the schematic configuration of the LD pumped solid state laser 50. Compared to the LD pumped solid state laser 10 illustrated in FIG. 1, the LD pumped solid state laser 50 is fundamentally different in that the solid state laser beam L3 is shortened in wavelength by a nonlinear optical material. In the LD pumped solid state laser 50, the concave mirror 20 is installed at an inclined angle with respect to the optical axis of the planar mirror 18, and a planar mirror 51 is installed such that optical axis thereof matches the reflection axis of the concave mirror 20. An LBO crystal (LiB₃O₁₅ crystal) 52 is a nonlinear optical material that converts the incident laser beam L3 having a wavelength of 640 nm into a second harmonic L4 having a wavelength of one half of 640 nm. Almost all of the second harmonic L4 laser beam passes through the concave mirror 20 and is output from the LD pumped solid state laser 50. A coating having a reflectance of 99.9% for light having a wavelength of 640 nm is administered on a light incident surface of the planar mirror 18. The concave mirror 20 has a curvature of 75 mm and a coating having a reflectance of 99% for light having a wavelength of 640 nm is administered on the reflective surface thereof. Solid state laser emission with an emission wavelength of 640 nm is realized by the configuration described above.

The second harmonic L4 having a wavelength of 320 nm is output from the concave mirror 20 and employed as utilization light. Almost all output is output from the concave mirror 20. In the LD pumped solid state laser 50, a pumping LD 11 with an output of 3.5 W was employed, and when the wavelength was converted using the LBO crystal 52 having a total length of 10 mm, a second harmonic L4 with a light output of approximately 250 mW could be obtained. In addition to the above LBO, other crystals such as a BBO (β-BaB₂O₄) crystal and a PPSLT (Periodically Poled Stoichiometric Lithium Tantalite) crystal may be employed as nonlinear optical materials for wavelength conversion.

### Fifth Embodiment

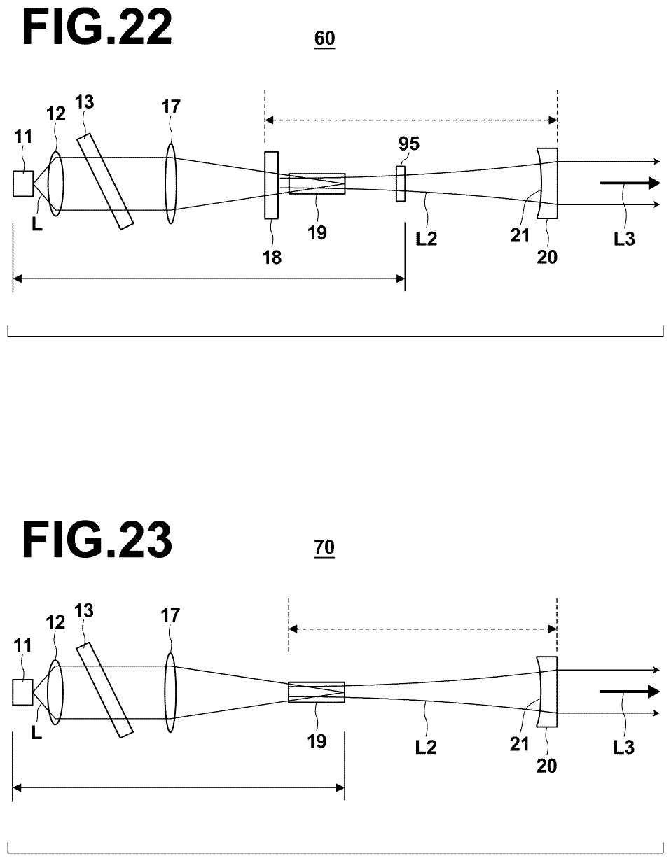

Referring next to FIG. 22, an LD pumped solid state laser 60 according to the fifth embodiment of the present disclosure is described. As illustrated in FIG. 22, the LD pumped solid state laser 60 has a pumping LD 11, a collimating lens 12, a narrow band BPF 13, a focusing lens 17, a planar mirror 18, a Pr:YLF crystal 19, and a concave mirror 20 similar to those illustrated in FIG. 1. A transmissive mirror 95 is provided between the Pr:YLF crystal 19 and the concave mirror 20 as a wavelength control means. An input surface of the transmissive mirror 95 has a reflectance of greater than 99% for light having a wavelength of 444 nm. Therefore, the pumping light beam L having a wavelength of 444 nm can be returned to the pumping LD 11. Thus, the pumping light beam L can be selected to be emitted mainly at a wavelength of 444 nm within a resonator (the range of which is indicated by the two ends of the dashed arrow in the drawing) constituted by the planar mirror 18 and the concave mirror 20.

In addition, the pumping light beam L having a wavelength of 444 nm can be absorbed by the Pr:YLF crystal 19 in both an emitted direction and a reflected direction and the reflectance of the planar mirror 95 for the light having a wavelength of 444 nm is 99% or greater. Therefore, the solid state laser 60 can emit light with high efficiency with little loss of the pumping light beam L. Meanwhile, since the transmittance of the resonator of the solid state laser is 99% or greater for light having a wavelength of 640 nm, a solid state laser having minimal loss of light having a wavelength of 640 nm and no reduction in light output power can be obtained. By adjusting the amount of Pr³⁺ doping and the crystal length, the Pr:YLF crystal 19 may, as an example, transmit 50% of light having a wavelength of 444 nm, absorb 75% of the reflected returning light having a wavelength of 444 nm, and utilize the remaining 25% for wavelength control.

The reflection and transmission characteristics of the input and output surfaces of the planar mirror 95 are summarized below.
Input surface: transmittance of 99% or greater for wavelength of 444 nm
   transmittance of 99% or greater for wavelength of 640 nm
Output surface: reflectance of 99% or greater for wavelength of 444 nm
   transmittance of 99% or greater for wavelength of 640 nm

### Sixth Embodiment

Referring next to FIG. 23, an LD pumped solid state laser 70 according to a sixth embodiment of the present disclosure will be described. As illustrated in FIG. 23, the LD pumped solid state laser 70 has the configuration of the fifth embodiment illustrated in FIG. 22, but without the transmissive mirror 95 and the planar mirror 18. The reflection and transmission characteristics of the input and output surfaces of the Pr:YLF crystal 19 are as follows.
Input surface: transmittance of 99% or greater for wavelength of 444 nm
   reflectance of 99% or greater for wavelength of 640 nm
Output surface: reflectance of 99% or greater for wavelength of 444 nm
   transmittance of 99% or greater for wavelength of 640 nm
      The above configuration is capable of exhibiting the same actions and effects as the configuration illustrated in FIG. 5. In addition, the cost of the LD pumped solid state laser 70 can be decreased by achieving further miniaturization and a reduction in the number of components compared to the configuration illustrated in FIG. 5.

### Seventh Embodiment

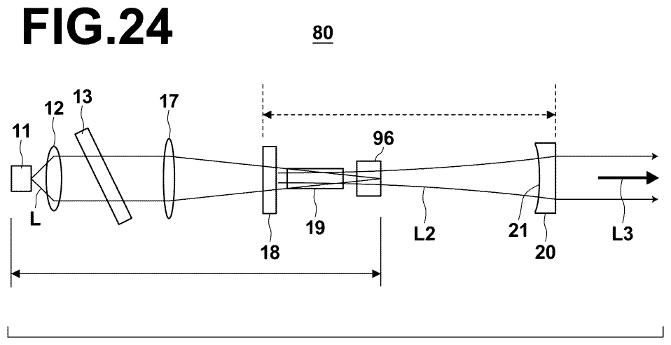

Referring next to FIG. 24, an LD pumped solid state laser 80 according to a seventh embodiment of the present disclosure will be described. As illustrated in FIG. 24, the LD pumped solid state laser 80 omits the transmissive mirror 95 from the configuration illustrated in FIG. 5, and is provided with a VBG (Volume Bragg Grating) 96 as a wavelength control means. The VBG has the function of diffracting only specific wavelengths and returning them to an original optical path. In in the present embodiment, only the wavelength of 444 nm is returned. Therefore, the wavelength of the pumping LD 11 becomes 444 nm. The reflection and transmission characteristics of the input and output surfaces of the VBG 96 are as follows.
Input surface: transmittance of 99% or greater for wavelength of 444 nm
   transmittance of 99% or greater for wavelength of 640 nm
Output surface: transmittance of 99% or greater for wavelength of 444 nm
   transmittance of 99% or greater for wavelength of 640 nm
      The above configuration is capable of exhibiting the same actions and effects as the configuration illustrated in FIG. 5.

### Eighth Embodiment

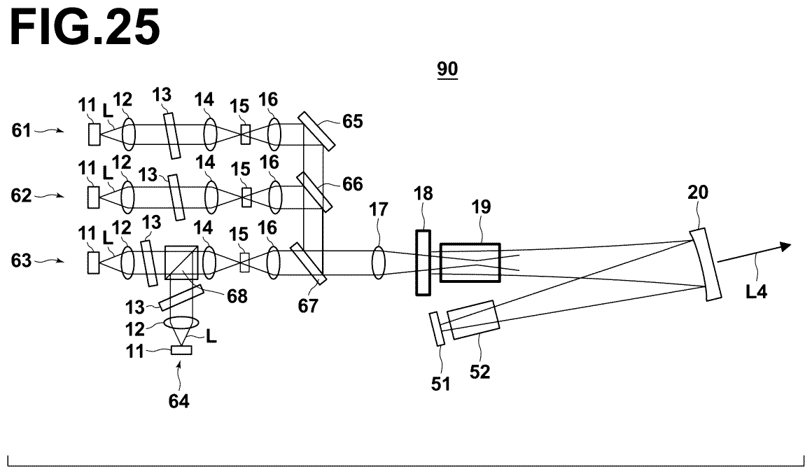

Referring next to FIG. 25, an LD pumped solid state laser 90 according to an eighth embodiment of the present disclosure will be described. FIG. 25 illustrates the schematic configuration of the LD pumped solid state laser 90, which differs fundamental wavely from the previously described embodiments in that a plurality of solid state laser crystals and a plurality of LDs for pumping the solid state laser crystals are provided. This point is also the same for the ninth through eleventh embodiments to be described below.

As illustrated in FIG. 25, the LD pumped solid state laser 90 according to the eighth embodiment is provided a total of four pumping systems consisting of a pumping LD 11, a collimating lens 12, and a narrow band BPF 13 arranged from top to bottom in the drawing. The four pumping systems are: a first pumping system 61, a second pumping system 62, a third pumping system 63, and a fourth pumping system 64. The first pumping system 61, the second pumping system 62, the third pumping system 63, and the fourth pumping system 64 which are arranged from top to bottom. In the first pumping system 61, the second pumping system 62, the third pumping system 63, and the fourth pumping system 64, each of the pumping LDs 11 is selected as appropriate, the passband of each of the narrow band BPFs 13 is set as appropriate, etc. The wavelengths of the pumping light beam L emitted by each of these systems are mainly 479 nm, 469 nm, 444 nm, and 442 nm, in this order.

The pumping light beam L emitted by the first pumping system 61 is reflected by a mirror 65 and then combined with the pumping light beam L emitted by the second pumping system 62 by a wavelength coupling mirror 66, which transmits light having a wavelength of 479 nm and reflects light having a wavelength of 469 m. The two pumping light beams L which are coupled are then coupled with the pumping light beam L emitted by the third pumping system 63 and the pumping light beam L emitted by the fourth pumping system 64 by a wavelength coupling mirror 67, which transmits light having wavelengths of 444 nm and 442 nm while reflecting light having wavelengths of 469 nm and 479 nm. The pumping light beam L emitted by the third pumping system 63 and the pumping light beam L emitted by the fourth pumping system 64 are combined by a polarizing beam splitter 68 before entering the wavelength coupling mirror 67 described above.

As in the LD pumped solid state laser 50 described previously with reference to FIG. 21, a planar mirror 18, a Pr:YLF crystal 19, a concave mirror 20, a planar mirror 51, and an LBO crystal 52 are provided. The actions of these components in the present embodiment are the same as those in the LD pumped solid state laser 50.

The present embodiment will be described in greater detail. As illustrated in FIG. 10, there are a total of four absorption lines in the Pr:YLF crystal 19: three with polarization π and one with polarization σ. The pumping LD 11 of the first pumping system 61 illustrated in FIG. 25 has an output of 1 W and an emission wavelength which is wavelength controlled to be 479 nm that matches one of the absorption lines of the

Pr:YLF crystal 19. Similarly, the pumping LD 11 in the second pumping system 62 has an output of 5 W and an emission wavelength which is controlled to be 469 nm. The pumping LD 11 in the third pumping system 63 has an output of 5 W and an emission wavelength which is controlled to be 444 nm. The pumping LD 11 in the fourth pumping system 64 has an output of 5 W and an emission wavelength which is controlled to be 442 nm. The pumping light beam L from the fourth pumping system 64 is rotated 90° in a polarization direction by the polarizing beam splitter 68 and is coupled with the pumping light beam L from the third pumping system 63. Because the wavelengths of the pumping light beams L emitted from the four pumping LDs 11 described above are all controlled by the narrow band BPF 13, about 90% absorption is achieved in the Pr:YLF crystal 19.

In the LD pumped solid state laser 90 having the above configuration, the output power of the pumping LD 11 of the first pumping system 61 is 1 W and the pumping light beam L emitted thereby is controlled to have a wavelength of 479 nm. In this case, the solid state laser emits light at a wavelength of 640 nm. Next, the LBO crystal 52 generates a second harmonic, and light output at a wavelength of 320 nm and an output of 0.1 W was obtained. Similarly, the output of the pumping LD 11 of the second pumping system 62 was 5 W and the pumping light beam L emitted thereby is controlled to have a wavelength of 469 nm. In this case, the solid state laser emitted light at a wavelength of 320 nm and a light output of 0.3 W was obtained. Similarly, the output of LD 11 for excitation in the third pumping system 63 is 5 W and the pumping light beam L emitted thereby is controlled have a wavelength of 444 nm. In this case, the solid state laser emitted light at a wavelength of 320 nm and a light output of 0.3 W was obtained. The pumping light beam L which is polarized and coupled by the polarizing beam splitter 68 has a light output of 5 W and a wavelength of 444 nm. Note that in the case that the light output of the polarized and coupled pumping light beam L is 5 W and the wavelength is controlled to be 442 nm, a solid state laser beam having a wavelength of 320 nm and having a light output of 0.3 can also be obtained. In addition, it is possible to obtain a solid state laser beam with an output of about 1.0 W by pumping the Pr:YLF crystal 19 with a high intensity pumping light beam which is a combination of all of the pumping light beams L from the first pumping system 61 through the fourth pumping system 64.

In the present embodiment, Pr:YLF crystals 19 with an amount of Pr doping of 0.5% and a total length of 10 mm were employed in order to increase absorption efficiency with respect to all wavelengths. The number of pumping light beams L to be coupled is not limited to four, and may be two or three. The method of wavelength control is not limited to a narrow band BPF, but can be one that has a second confocal point without a BPF, or one that utilizes a third diffraction grating. Further, the wavelength control means may be that which employs a VBG (Volume Bragg Grating: type volume holographic diffraction grating).

### Ninth Embodiment

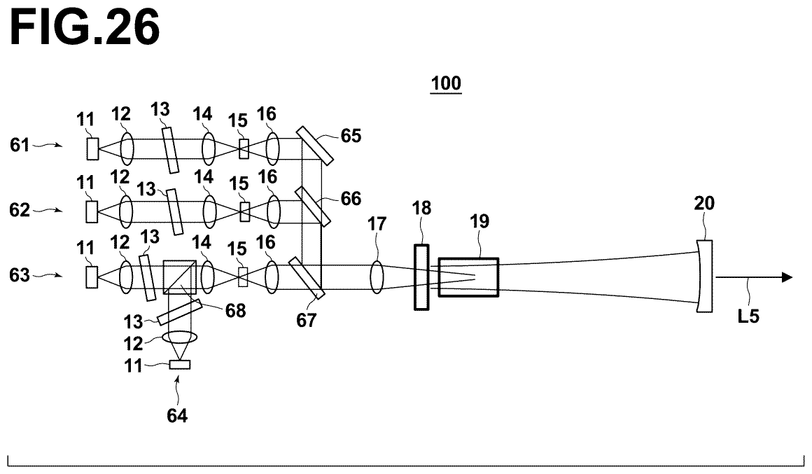

Referring next to FIG. 26, an LD pumped solid state laser 100 according to a ninth embodiment of the present disclosure will be described. As can be seen in the schematic configuration illustrated in FIG. 26, the LD pumped solid state laser 100 is an aspect in which the planar mirror 51 and the LBO crystal 52 are removed from the LD pumped solid state laser 90 illustrated in FIG. 25. The concave mirror 20 is equivalent to that in the above LD pumped solid state laser 90, including the coating on the concave surface, which is not shown in the drawing. Therefore, in the LD pumped solid state laser 100, light having a wavelength of 640 nm is output from the concave mirror 20. The light output is 1.2 W, for example.

### Tenth Embodiment

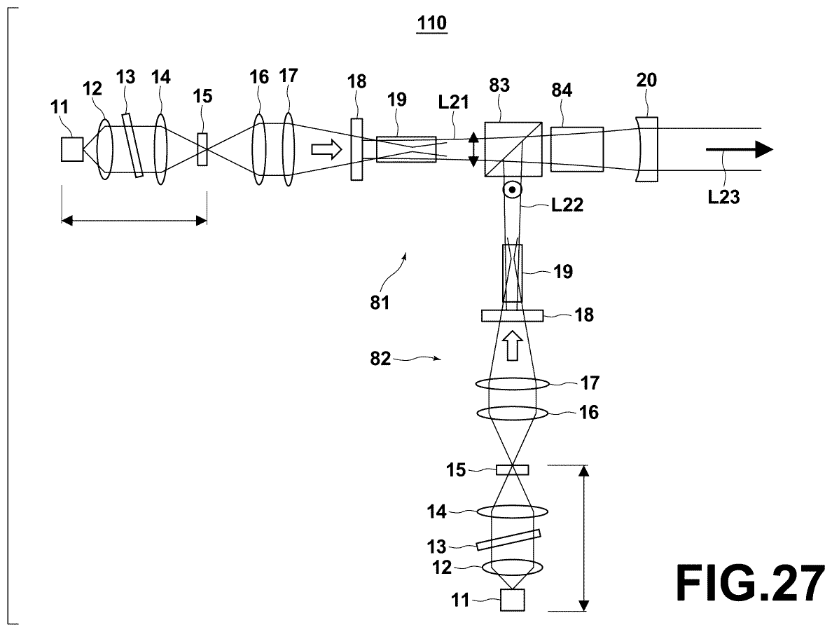

Referring next to FIG. 27, an LD pumped solid state laser 110 according to a tenth embodiment of the present disclosure will be described. As can be seen in the schematic configuration illustrated in FIG. 27, the LD pumped solid state laser 110 has a configuration in which a laser beam L21 having a wavelength of 721 nm generated in a first pumping and emission system 81 and a laser beam L22 having a wavelength of 698 nm generated in are second pumping and emission system 82 are coupled by a polarizing beam splitter 83.

The laser beam L21 having a wavelength of 721 nm generated in the first pumping and emission system 81 and the laser beam L22 having a wavelength of 698 nm generated in the second pumping and emission system 82 have mutually perpendicular electrical field emission directions, and the laser beams L21 and L22 are coupled by the polarizing beam splitter 83. The coupled laser beams L21 and L22 enter a BBO crystal (β-BaB₂O₄ crystal) 84, which is a nonlinear optical material, and are converted to a sum frequency L23 having a wavelength of 355 nm by the BBO crystal 84. This sum frequency L23 passes through the concave mirror 20 and is output from the LD pumped solid state laser 110 as utilization light.

The configuration above will be described in greater detail below. The optical system from the pumping light beam L being emitted from the pumping LD 11, undergoing wavelength control by the narrow band BPF 13, and entering the Pr:YLF crystal 19 is the same in the above first pumping and emission system 81 and second pumping and emission system 82. The pumping light beam L, whose wavelength is controlled to 444 nm by the first pumping and emission system 81, passes through the planar mirror 18 and is absorbed by the Pr:YLF crystal 19. The light generated from the Pr:YLF crystal 19 by the absorption is caused to resonate between the planar mirror 18 and the concave mirror 20 to obtain a laser beam L21 having a wavelength of 721 nm. The laser beam L21 having the above wavelength can be obtained by designing the reflective coat of the planar mirror 18 to have a reflectance of 99.9% or higher with respect to light having a wavelength of 721 nm.

The laser beam L21 having a wavelength of 721 nm is emitted as p-polarized light having a polarization orientation parallel to the drawing plane of FIG. 27. Similarly, the coating of the planar mirror 18 of the second pumping and emission system 82 is designed to have a reflectance of 99.9% or higher for light having a wavelength of 698 nm, such that a laser beam L22 having the above wavelength can be obtained. The laser beam L22 having a wavelength of 698 nm is emitted as s-polarized light having a polarization orientation perpendicular to the drawing plane of FIG. 27. At this time, the laser beam L21 having a wavelength of 721 nm and the laser beam L22 having a wavelength of 698 nm can be emitted simultaneously because the polarizing beam splitter 83 is located in both resonators. The polarizing beam splitter 83 is coated to transmit the 721-nm wavelength light with a transmittance of 99.9% or greater while reflecting the 698-nm wavelength light with a reflectance of 99.9% or greater, such that the propagation loss of the laser beam L21 and L22 at each wavelength is almost zero.

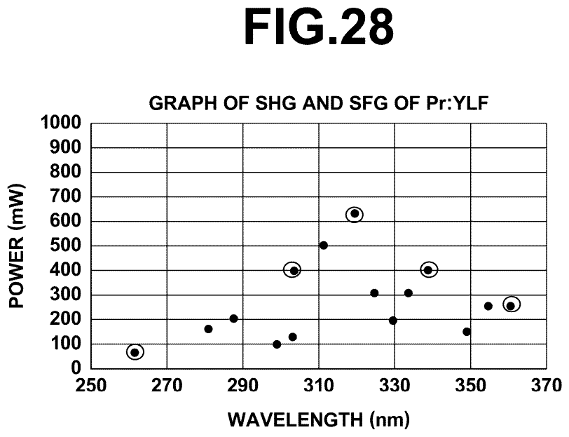

Hereinafter, examples of light output and wavelength of second harmonics and sum frequency light obtained by wavelength conversion in the present disclosure will be described with reference to FIG. 28. The black dots in the drawing denote examples of light output and wavelength of the second harmonic, and the circles that surround the black dots in the drawing denote examples of the light output and wavelength of sum frequency light.

### Eleventh Embodiment

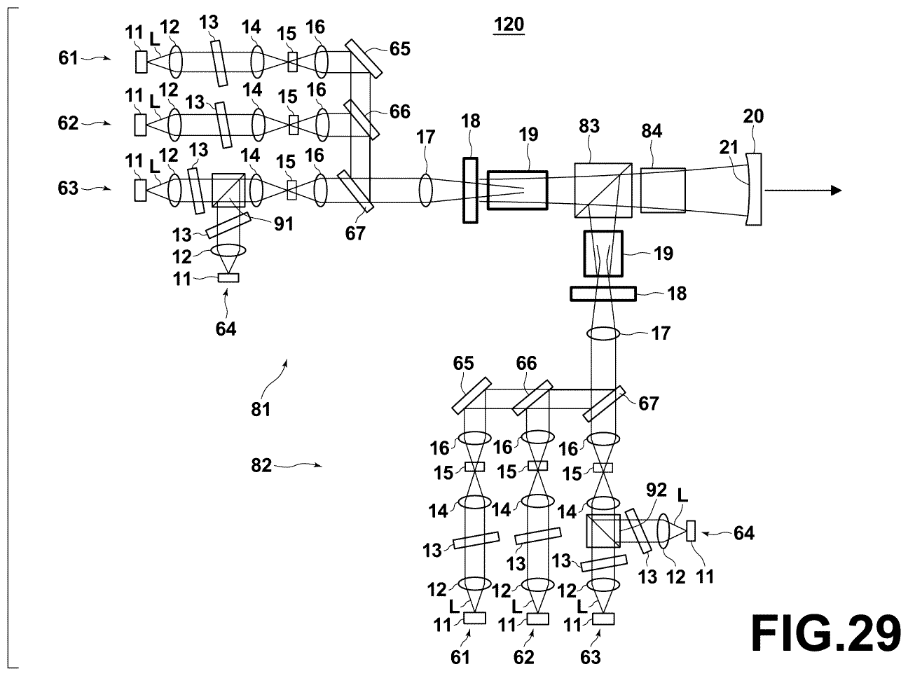

Referring next to FIG. 29, an LD pumped solid state laser 120 according to an eleventh embodiment of the present disclosure will be described. As illustrated in FIG. 29, the LD pumped solid state laser 120 has a configuration in which a laser beam L1 having a wavelength of 721 nm generated by the first pumping and emission system 81 and a laser beam L2 having a wavelength of 698 nm generated by the second pumping and emission system 82 are combined by a polarization beam splitter 83. The above first pumping and emission system 81 is equivalent to that illustrated in FIG. 26, and has a first pumping system 61, a second pumping system 62, a third pumping system 63, and a fourth pumping system 64.

The first pumping and emission system 81 will be described in detail. The first pumping system 61 thereof is constituted by a pumping LD 11, a collimating lens 12, a narrow band BPF 13, a focusing lens 14, a transmissive planar mirror 15, a collimating lens 16, and a mirror 65, arranged sequentially from left to right along an optical axis that extends horizontally in FIG. 29. The second pumping system 62 is also constituted by a pumping LD 11, a collimating lens 12, a narrow band BPF 13, a focusing lens 14, a transmissive planar mirror 15, and a collimating lens 16, and additionally a wavelength coupling mirror 66. The third pumping system 63 is also constituted by a pumping LD 11, a collimating lens 12, a narrow band BPF 13, a focusing lens 14, a transmissive planar mirror 15, and a collimating lens 16 (these components are shared with those of the fourth pumping system 64 to be described below), and additionally a wavelength coupling mirror 67. The fourth pumping system 64 is constituted by the pumping LD 11, the collimating lens 12, and the narrow band BPF 13, and additionally a polarizing beam splitter 91.

Similarly, the second pumping and emission system 82 has a first pumping system 61, a second pumping system 62, a third pumping system 63, and a fourth pumping system 64. The first pumping system 61 through the fourth pumping system 64 of the second pumping and emission system 82 will be described below. The first pumping system 61 is constituted by a pumping LD 11, a collimating lens 12, a narrow band BPF 13, a focusing lens 14, a transmissive planar mirror 15, a collimating lens 16, and a mirror 65, arranged sequentially from bottom to top along an optical axis extending vertically in the drawing. The second pumping system 62 is also constituted by a pumping LD 11, a collimating lens 12, a narrow band BPF 13, a focusing lens 14, transmissive planar mirror 15, and a collimating lens 16, and additionally a wavelength coupling mirror 66. The third pumping system 63 is also constituted by a same pumping LD 11, a collimating lens 12, a narrow band BPF 13, a focusing lens 14, a transmissive planar mirror 15, and a collimating lens 16 (the above components are shared with those of the fourth pumping system 64 to be described below), and additionally a wavelength coupling mirror 67. The fourth pumping system 64 is constituted by the pumping LD 11, the collimating lens 12, and the narrow band BPF 13, and additionally a polarizing beam splitter 92.

The action of the above first pumping and emission system 81 will be described. A pumping light beam L1 emitted by the first pumping system 61 is reflected by the mirror 65 and then coupled with a pumping light beam L1 emitted by the second pumping system 62 by the wavelength coupling mirror 66. After being coupled, the pumping light beam L1 emitted by the second pumping system 62 and a pumping light beam L1 emitted by the fourth pumping system 64 are coupled by the wavelength coupling mirror 67. A pumping light beam L1 emitted by the third pumping system 62 and the pumping light beam L1 emitted by the fourth pumping system 64 are coupled by the polarization beam splitter 91 before entering the wavelength coupling mirror 67.

As described above, the high intensity pumping light beam L1, which is emitted from a total of four pumping systems and then merged into a single beam, enters the two Pr:YLF crystals 19 from two directions, such that pumping is performed well and a high intensity laser beam L2 can be obtained. In such a case, it is possible to obtain a high intensity wavelength conversion wave when the laser beam L2 is undergoes wavelength conversion to a second harmonic or a sum frequency.

The laser beam L1 having a wavelength of 721 nm generated by the first pumping and emission system 81 and the laser beam L2 having a wavelength of 698 nm generated by the second pumping and emission system 82 have mutually perpendicular electrical field emission directions, and the laser beams L21 and L22 are coupled by the polarizing beam splitter 83. The coupled laser beams L21 and L22 enter a BBO crystal (β-BaB₂O₄ crystal) 84, which is a nonlinear optical material, and are converted to a sum frequency L23 having a wavelength of 355 nm by the BBO crystal 84. The sum frequency L23 passes through the concave mirror 20 and is emitted outside the LD pumped solid state laser 120 as utilization light.

As described above, by performing wavelength conversion utilizing a nonlinear optical crystal, it is possible to generate a variety of laser beams having wavelengths shorter than a fundamental wave. Below are examples in the order of wavelengths of laser beams to be generated, the wavelength (type) of an original laser beam, and the wavelength conversion method to be employed. Note that as wavelength conversion methods, “SHG” refers to second harmonic generation, and “SFG” refers to sum frequency generation.
262 nm/523 nm (fundamental wave)/SHG
281 nm/607 nm (fundamental wave) and 532 nm (fundamental wave) SFG
288 nm/639 nm (fundamental wave) and 532 nm (fundamental wave) SFG
299 nm/698 nm (fundamental wave) and 532 nm (fundamental wave) SFG
303 nm/721 nm (fundamental wave) and 532 nm (fundamental wave) SFG
304 nm/607 nm (fundamental wave) SHG
311 nm/639 nm (fundamental wave) and 607 nm (fundamental wave) SFG
320 nm/639 nm (fundamental wave) SHG
325 nm/698 nm (fundamental wave) and 607 nm (fundamental wave) SFG
330 nm/721 nm (fundamental wave) and 607 nm (fundamental wave) SFG
334 nm/698 nm (fundamental wave) and 639 nm (fundamental wave) SFG
339 nm/721 nm (fundamental wave) and 639 nm (fundamental wave) SFG
349 nm/698 nm (fundamental wave) SHG
355 nm/721 nm (fundamental wave) and 698 nm (fundamental wave) SFG
361 nm/721 nm (fundamental wave) SHG

In each of the embodiments described above, an LD that emits a laser beam by itself is employed as the pumping LD 11. Alternatively, an LD that does not emit a laser beam by itself, that is, an LD with an AR (antireflective) coating on the output end facet thereof may be employed.

### Twelfth Embodiment

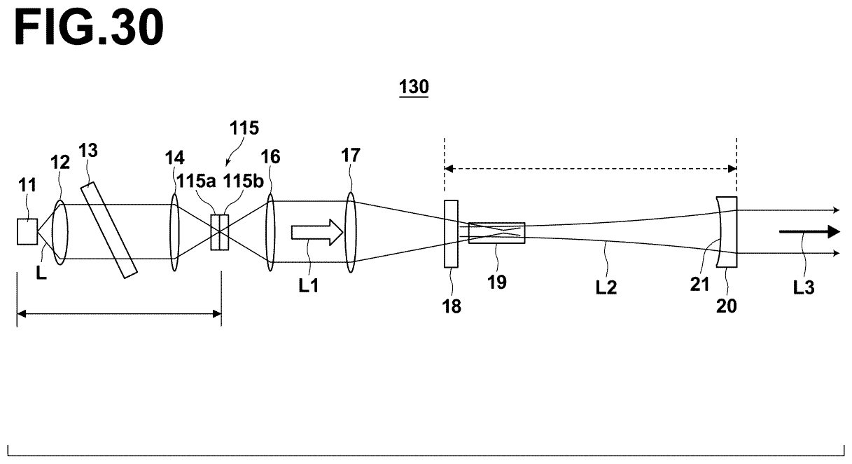

Referring next to FIG. 30, an LD pumped solid state laser 130 according to a twelfth embodiment of the present disclosure will be described. As can be seen from the schematic configuration illustrated in FIG. 30, the LD pumped solid state laser 130 differs from the configuration illustrated in FIG. 1 in that a transmissive reflective mirror 115 is provided instead of the transmissive planar mirror 15, while the other points are basically the same as in FIG. 1. Therefore, in the following, descriptions of the configurations similar to that of FIG. 1 will be omitted, and the point of difference will be described.

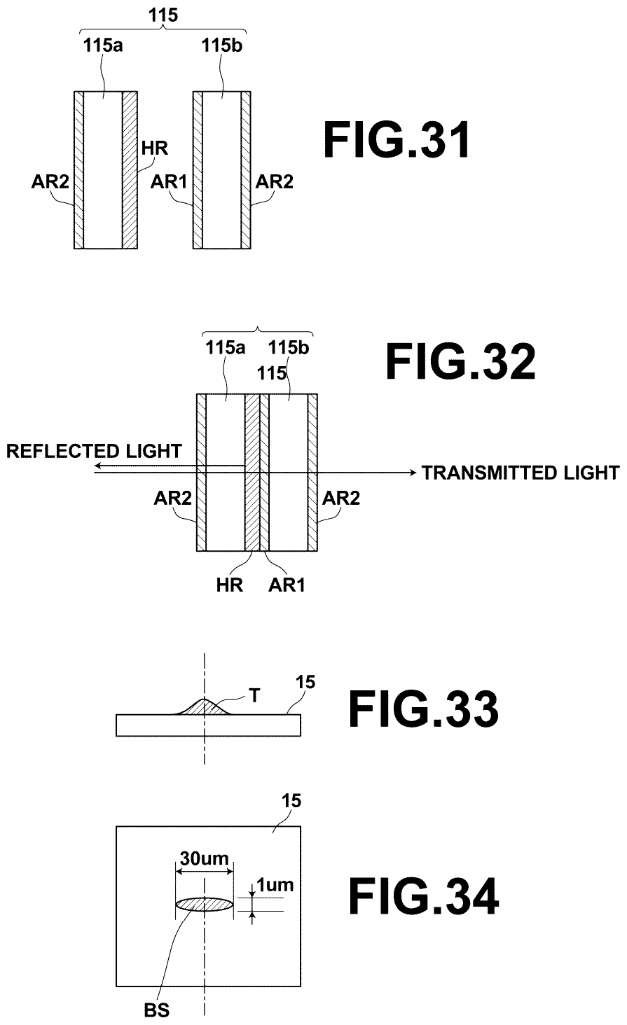

The transmissive reflective mirror 115 is formed by coupling two glass plates 115a and 115b, each of which is a parallel plate and rectangular or circular in shape, as illustrated in detail in FIG. 31. A first surface of the glass plate 115a is coated with an antireflective coating film (AR2), while a second surface is coated with a highly reflective coating film (HR). Both of a first surface and a second surface of another glass plate 115b are coated with antireflective coating films AR1 and AR2.

The highly reflective coating film HR is constituted by a multilayer film of HfO₂. Ta₂, O₅, TiO₂, etc., while the antireflective coating films AR1 and AR2 are constituted by SiO₂ films, for example. The antireflective coating film AR1 is designed and produced to have a reflectance of 0.5% or less after the glass plates are coupled, and the antireflective coating film AR2 is designed and produced to have a reflectance of 0.5% or less in air.

After the antireflective coating films AR1 and AR2 and the highly reflective coating film HR were produced as described above, the surfaces of the antireflective coating film AR1 and the highly reflective coating film HR were activated by ozone treatment, plasma treatment, or UV light treatment, and then the two glass plates 115a and 115b were coupled by overlaying the surfaces thereof (refer to FIG. 32). The coupling was performed in air or in a vacuum. In this case, the two glass plates 115a and 115b were coupled by so-called optical contact. After coupling, the reflectance of the coupled area was examined using a laser beam for measuring reflectance, and the reflectance was 30%. The measurement of reflectance can also be performed using the pumping light beam L in the configuration illustrated in FIG. 30. In this case, the reflectance was also 30%. Further, the reflectance can also be measured employing a commonly utilized spectrometer.

The LD pumped solid state laser 130 according to the twelfth embodiment is formed by coupling the two glass plates 115a and 115b and arranging them as the transmissive reflective mirror 115 as illustrated in FIG. 30. In this configuration, the pumping light beam L is focused by the focusing lens 14 to be focused at the junction surface of the two glass plates 115a and 115b. 70% of the pumping light beam L is transmitted through the transmissive reflective mirror 115, and the remaining 30% is reflected at the above junction surface (more specifically, by the highly reflective coated film HR) and returns toward the pumping LD 11 (refer to FIG. 32).

The position at which the focused pumping light beam Lis focused in the present embodiment is sandwiched between the two glass plates 115a and 115b, such that the beam profile of the pumping light beam L at the focusing position can be maintained normal. The beam profile will be described in detail below.

First, as in the configuration illustrated in FIG. 1, when the pumping light beam L is focused on one surface of the transmissive planar mirror 15 and is energized for a long time, its beam profile becomes abnormal over time. There is a tendency for this to occur particularly in a case in which a confocal optical system is provided and the emission wavelength is also controlled, as in the configuration illustrated in FIG. 1. That is, at the mirror surface that constitutes the external resonator (the resonating range is indicated by the two ends of the solid arrow in FIG. 1), the beam spot of the focused pumping light beam L is small, and therefore the optical power density thereof is high. The higher optical power density causes it to be more likely for the beam profile to become abnormal. Note that long term energization here refers to continuous operation at a constant light output for several hundred hours or longer, or continuous operation for several thousand hours or longer.

For example, if the pumping light beam L has a short wavelength of blue to violet and a high light output of several hundred mW to greater than 1 W, a photochemical reaction is induced at the focusing position of the pumping light beam L when the pumping LD 11 is energized for a long time. As a result, organic matter floating in the surrounding atmosphere is gradually deposited on the mirror surface. Due to the deposited organic matter, the beam profile of the pumping light beam L which is focused on the mirror surface gradually changes from a normal Gaussian beam shape to an abnormal beam profile.

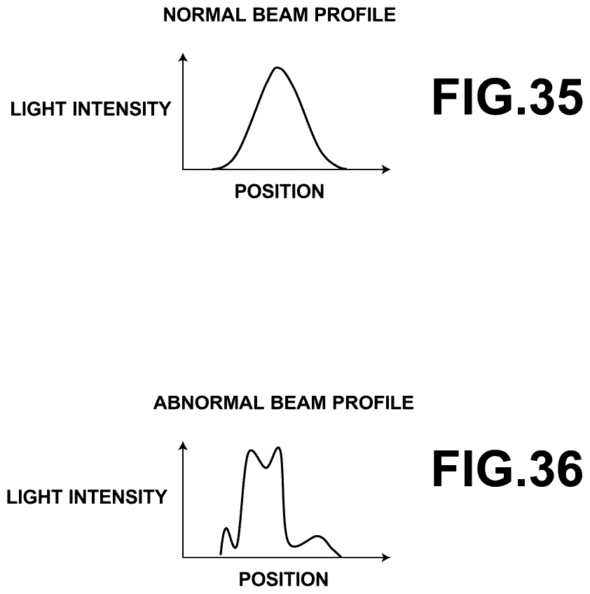

An example of the schematic side profile of deposited matter T is illustrated in FIG. 33 for a case in which the deposition of organic matter described above occurs on one surface of the transmissive planar mirror 15 in the configuration illustrated in FIG. 1. An example of the schematic planar profile of a beam spot BS affected by the deposited matter T is illustrated in FIG. 34. A normal beam profile of the pumping light beam L, which is a Gaussian beam shape, is illustrated in FIG. 35, and an example of an abnormal beam profile is illustrated in FIG. 36. The abnormal beam profile shape is not limited to the profile shape illustrated in FIG. 36, but can change into various disordered shapes due to differences in the conditions of operating environments. Because of this significant difference from the Gaussian beam shape which is employed in normal optical design, the reflected light does not return normally to the pumping LD 11, and wavelength control is not sufficiently achieved. Further, the beam of the pumping light beam L1 will also have an abnormal beam profile shape. Therefore, the beam cannot be narrowed in the YLF crystal 19 as designed, resulting in the failure of normal laser emission. The beam profiles are illustrated with the horizontal axis representing positions and the vertical axis representing light intensities.

As illustrated in FIG. 30, the position where the pumping light beam L is focused is sandwiched between the two glass plates 115a and 115b, which prevents organic matter floating in the atmosphere around the glass plates 115a and 115b from being deposited onto the focusing position. Therefore, the beam profile of the pumping light beam L does not become abnormal due to the influence of such deposited matter, and a normal Gaussian beam shape is maintained.

### Thirteenth Embodiment

Next, a thirteenth embodiment of the present disclosure will be described. Compared to the LD pumped solid state laser 130 of the twelfth embodiment illustrated in FIG. 30, the configuration of the transmissive reflective mirror 115 differs (therefore a different method of production) in the LD pumped solid state laser of the thirteenth embodiment, but is basically the same as the configuration illustrated in FIG. 30 in other points. Therefore, the following description will mainly focus on the point of difference from the configuration illustrated in FIG. 30. This also applies to a fourteenth embodiment and a fifteenth embodiments, which will be described later.

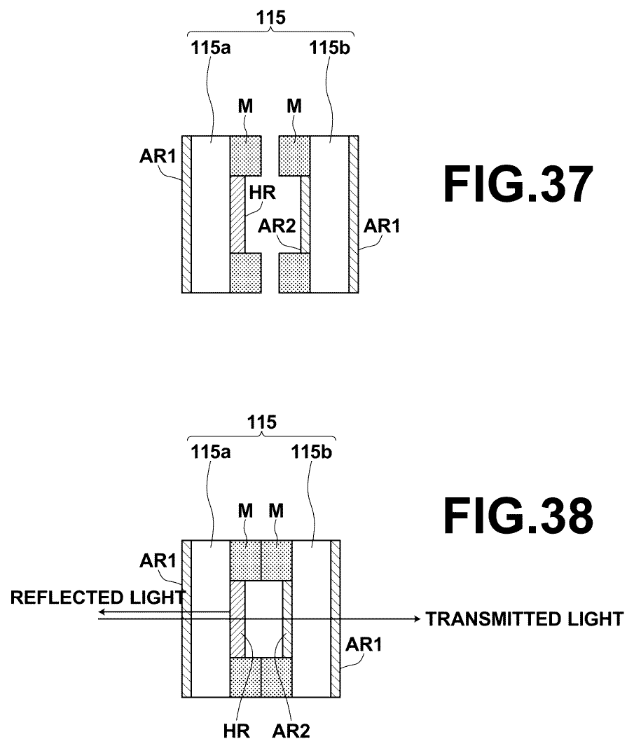

In the present embodiment, two glass plates 115a and 115b are coupled by welding metals M arranged in the vicinity of the inner peripheral edges thereof. FIG. 37 and FIG. 38 schematically illustrate the state of the metals M prior to and following welding, respectively. As illustrated in these drawings, the interior of an annular metal M is coated with a highly reflective coating film HR on a first surface of the glass plate 115a.

The interior of an annular metal M is coated with an antireflective coating film AR2 on a first surface of the glass plate 115b. Second surfaces of the glass plates 115a and 115b are each coated with an antireflective coating film AR1.

The above highly reflective coating film HR is constituted by multiple layers of HfO₂, Ta₂O₅, TiO₂, etc., and the antireflective coating films AR1 and AR2 are constituted by SiO₂ films, for example. The antireflective coating film AR1 is designed and produced to have a reflectance of 0.5% or less in air, and the antireflective coating film AR2 is designed and manufactured to have a reflectance of 0.5% or less in an inert gas environment.

After the above coating films HR, AR1 and AR2 are formed, NiCr or Cr is deposited on the periphery of the glass plates 115a and 115b (a predetermined area from the periphery toward the center) as a base coating, and AuSn (80% Au by weight) is plated on the NiCr or Cr to a thickness of 10 μm. This plated area is denoted as the metal M in FIGS. 37 and 38.

When the glass plates 115a and 115b are overlaid such that the above plated areas overlap and heated to a temperature above the melting point of AuSn, which is 280° C., the AuSn melts and the glass plates 115a and 115b are coupled (the state illustrated in FIG. 38). This coupling by welding should be performed in an environment of an inert gas such as dry N₂ with a dew point temperature of −50° C. or lower. In addition to dry N₂, argon and other gases are also applicable as inert gases.

The LD pumped solid state laser according to the sixth embodiment was obtained by applying the transmissive reflective mirror 115 consisting of the glass plates 115a and 115b described above to the configuration illustrated in FIG. 1. In the sixth embodiment, the beam profile at the focusing position of the pumping light beam L is maintained normal. This is also true in the present embodiment, because the focusing position of the pumping light beam Lis sandwiched between glass plates 115a and 115b and particularly in this case, because both glass plates are coupled via welded metal.

That is, in this case, the area between the two glass plates 115a and 115b is highly airtight, and if anything is present in this area, it is only inert gas, so no organic matter or the like can penetrate the area, and no deposition of organic matter or the like (refer to FIG. 33) can be generated. Therefore, the beam profile of the pumping light beam L does not become abnormal due to the influence of deposited matter, and is maintained in a normal state.

### Fourteenth Embodiment

Next, the fourteenth embodiment of the present disclosure will be described. In the fourteenth embodiment, as in the thirteenth embodiment, two glass plates 115a and 115b are coupled by welding metal to metal in the vicinity of the peripheries thereof. However, but the method of generating the metal for coupling is different from that of the thirteenth embodiment. The generation of the welding metal will be described below.

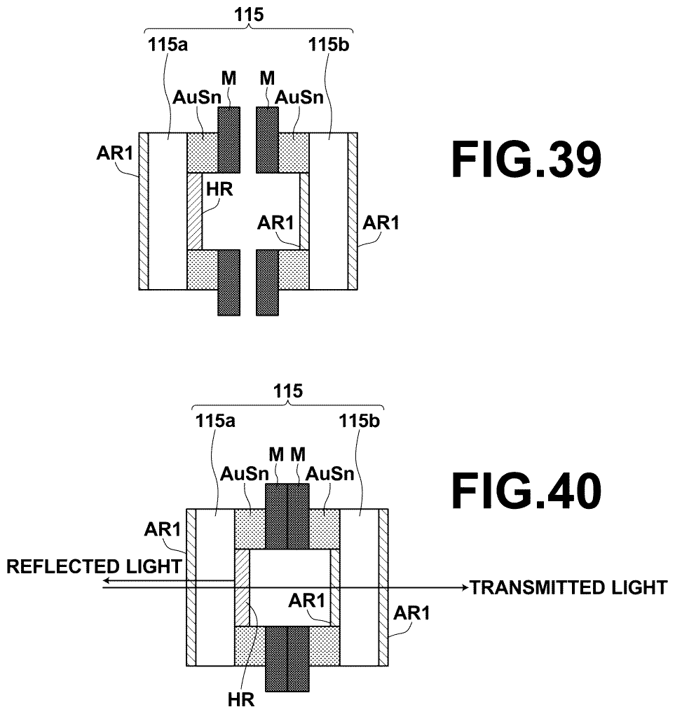

FIG. 39 and FIG. 40 illustrate a schematic representation of the welding metal M described above prior to and following welding, respectively. As illustrated in these drawings, the interior of an annular metal M is coated with a highly reflective coating film HR on a first surface of the glass plate 115a. The interior of an annular metal M is coated with an antireflective coating film AR2 on a first surface of the glass plate 115b. Second surfaces of the glass plates 115a and 115b are each coated with an antireflective coating film AR1.

The above highly reflective coating film HR is constituted by multiple layers of HfO₂, Ta₂O₅, TiO₂, etc., and the antireflective coating films AR1 and AR2 are constituted by SiO₂ films, for example. The antireflective coating film AR1 is designed and produced to have a reflectance of 0.5% or less in air, and the antireflective coating film AR2 is designed and manufactured to have a reflectance of 0.5% or less in an inert gas environment.

After the above coating films HR, AR1, and AR2 are formed, NiCr or Cr is deposited on the periphery of the glass plates 115a and 115b (a predetermined area from the periphery toward the center side), and AuSn (80% Au by weight) is plated on the NiCr or Cr to a thickness of 10 μm. Note that the plated portions are omitted in FIGS. 39 and 40.

After the above plating is applied, when AuSn is heated to a temperature above the melting point of AuSn, which is 280° C., the AuSn melts and adheres to the glass plate 115a and the metal M, and also adheres to the glass plate 115b and the metal M (the state illustrated in FIG. 39). Next, when the glass plates 115a and 115b are overlaid such that the portions of the metal M overlap, and the metal M is further is heated to a temperature above the melting point of AuSn, which is 280° C., the glass plates 115a and 115b are coupled via the melted metal M (the state illustrated in FIG. 40).

This coupling by welding should be performed in an environment of an inert gas such as dry N₂ with a dew point temperature of −50° C. or lower. In addition to dry N₂, argon and other gases are also applicable as inert gases. In such a case, a hermetically sealed inert gas void is formed between the glass plates 115a and 115b.

After the adherence of the glass plate 115a to the metal M and the glass plate 115b to the metal M illustrated in FIG. 39 above, the melting point of AuSn becomes higher because Au has diffused into AuSn. Therefore, when the glass plates 115a and 115b are coupled as illustrated in FIG. 40, the AuSn is prevented from melting and peeling off the above adhesion which was previously performed. Alternatively, AuSn with different composition ratios (composition ratios of Au and Sn, for example) and different melting points may be applied to prevent peel off both in the case of the above adhesion and the case of coupling.

### Fifteenth Embodiment

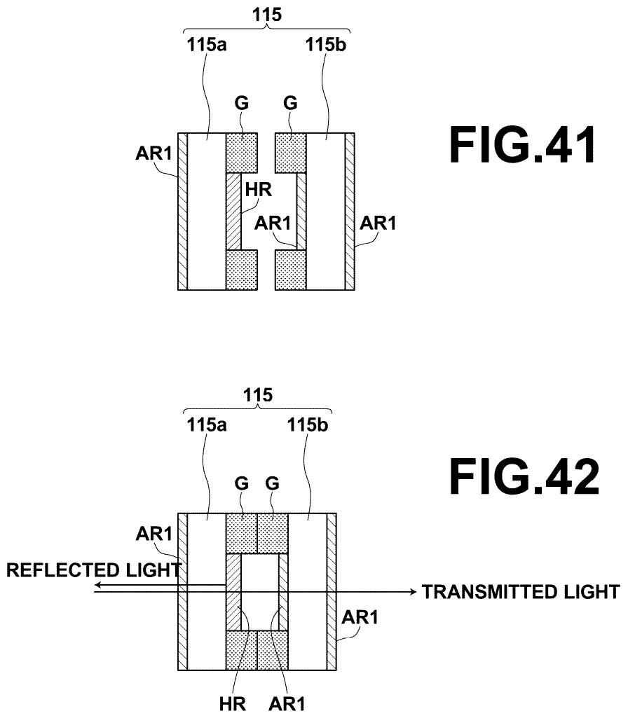

Next, the fifteenth embodiment of the present disclosure will be described. In the fifteenth embodiment, the two glass plates 115a and 115b are coupled using low melting point glass. FIGS. 41 and 42 will be employed below to explain the coupling.

FIG. 41 and FIG. 42 illustrate a schematic representation of the glass plates 115a and 115b prior to and following being coupled, respectively. As illustrated in these drawings, the interior of a low melting point glass G is coated with a highly reflective coating film HR on a first surface of the glass plate 115a. The interior of a low melting point glass G is coated with an antireflective coating film AR2 on a first surface of the glass plate 115b. Second surfaces of the glass plates 115a and 115b are each coated with an antireflective coating film AR1.

The above highly reflective coating film HR is constituted by multiple layers of HfO₂, Ta₂O₅, TiO₂, etc., and the antireflective coating films AR1 and AR2 are constituted by SiO₂ films, for example. The antireflective coating film AR1 is designed and produced to have a reflectance of 0.5% or less in air, and the antireflective coating film AR2 is designed and manufactured to have a reflectance of 0.5% or less in an inert gas environment.

After the coating film HR is formed and the low melting point glass G is melted, the glass plates 115a and 115b are coupled (the state illustrated in FIG. 42). A lead free mixture of Ta₂O₅ (tellurium dioxide) and MoO₃ (molybdenum trioxide) glass powders was employed as the low melting point glass G. The glass powder mixture was applied to the periphery of each of the glass plates 115a and 115b, and the portions to which the glass powder mixture was applied was heated to the melting point thereof, which is 380° C., or greater to melt and bond the low melting point glasses G to each other. Thereby, the glass plates 115a and 115b are coupled together, but an airtight void of inert gas is formed therebetween.

A mixture of PbO, B₂O₃, and SiO₂ can also be employed as the glass powder mixture described above. In this case, the above heating is performed at 500° C., which is above the melting point of the mixture. When the low melting point glass G is melted in this manner and the glass plates 115a and 115b are coupled to form the LD pumped solid state laser 130 illustrated in FIG. 30, the beam profile of the pumping light beam at the focusing position of the pumping light beam L can be maintained in a normal Gaussian beam shape as in the previously described embodiments. Therefore, in this case as well, the generation of deposited matter T due to long term energization as illustrated in FIG. 33 is considered to be suppressed.

What is claimed is:

1. A semiconductor laser pumped solid state laser, comprising:
a solid state laser crystal;
a semiconductor laser that emits a pumping light beam to pump the solid state laser crystal;
a resonator that resonates the light emitted from the solid state laser crystal when the solid state laser crystal is pumped; and
a wavelength control means for causing the emission wavelength of the pumping light beam emitted by the semiconductor laser to match an absorption peak wavelength of the solid state laser crystal.

2. The semiconductor laser pumped solid state laser as defined in claim 1, wherein the wavelength control means comprises a bandpass filter that narrows the wavelength of the light to be resonated placed in the resonator.

3. The semiconductor laser pumped solid state laser as defined in claim 1, wherein the resonator further comprises a diffraction grating that selects the wavelength of the light to be resonated.

4. The semiconductor laser pumped solid state laser as defined in claim 1, wherein the resonator further comprises a VBG (Volume Bragg Grating) that selects the wavelength of the light to be resonated.

5. The semiconductor laser pumped solid state laser as defined in claim 1, wherein the resonator further comprises a confocal optical system.

6. The semiconductor laser pumped solid state laser as defined in claim 1, further comprising:
an external resonator that constitutes the wavelength control means,
wherein the external resonator comprising a transmissive reflective mirror that transmits the pumping light beam emitted by the semiconductor laser toward the solid state laser crystal and reflects the pumping light beam toward the semiconductor laser, and
wherein the transmissive reflective mirror being formed by two glass plates which are coupled to each other.

7. The semiconductor laser pumped solid state laser as defined in claim 6, wherein the two glass plates are coupled to each other by optical contact.

8. The semiconductor laser pumped solid state laser as defined in claim 6, wherein the two glass plates are coupled to each other by forming metal plating in the vicinity of the edges of each glass plate, then heating and welding the metal plating.

9. The semiconductor laser pumped solid state laser as defined in claim 6, wherein the two glass plates are coupled to each other by forming metal plating and a metal plate overlapping the metal plating in the vicinity of the edges of each glass plate, then heating and welding the metal plates via the metal plating.

10. The semiconductor laser pumped solid state laser as defined in claim 6, wherein the two glass plates are coupled to each other by melting low melting point glass provided in the vicinity of the edges of each glass plate.

11. The semiconductor laser pumped solid state laser as defined in claim 1,
wherein the solid state laser crystal is doped with Pr³⁺.

12. The semiconductor laser pumped solid state laser as defined in claim 1, further comprising:
a wavelength converting element that shortens the wavelength of a laser beam emitted by the solid state laser.

13. The semiconductor laser pumped solid state laser as defined in claim 2, wherein the resonator further comprises a confocal optical system.

14. The semiconductor laser pumped solid state laser as defined in claim 2, further comprising:
an external resonator that constitutes the wavelength control means,
wherein the external resonator comprising a transmissive reflective mirror that transmits the pumping light beam emitted by the semiconductor laser toward the solid state laser crystal and reflects the pumping light beam toward the semiconductor laser, and
wherein the transmissive reflective mirror being formed by two glass plates which are coupled to each other.

15. The semiconductor laser pumped solid state laser as defined in claim 14, wherein the two glass plates are coupled to each other by optical contact.

16. The semiconductor laser pumped solid state laser as defined in claim 14, wherein the two glass plates are coupled to each other by forming metal plating in the vicinity of the edges of each glass plate, then heating and welding the metal plating.

17. The semiconductor laser pumped solid state laser as defined in claim 14, wherein the two glass plates are coupled to each other by forming metal plating and a metal plate overlapping the metal plating in the vicinity of the edges of each glass plate, then heating and welding the metal plates via the metal plating.

18. The semiconductor laser pumped solid state laser as defined in claim 14, wherein the two glass plates are coupled to each other by melting low melting point glass provided in the vicinity of the edges of each glass plate.

19. The semiconductor laser pumped solid state laser as defined in claim 2, wherein the solid state laser crystal is doped with Pr³⁺.

20. The semiconductor laser pumped solid state laser as defined in claim 2, wherein the semiconductor laser is a GaN semiconductor laser.
